(19) United States
(12) Patent Application Publication
(10) Pub. No.: US 2025/0374608 A1
(43) Pub. Date: Dec. 4, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Kuo-Chang CHIANG, Hsinchu City (TW); Yun-Feng KAO, New Taipei City (TW); Chih-Yu CHANG, New Taipei City (TW); Min-Yen CHUANG, Hsinchu City (TW); Wu-Wei TSAI, Taoyuan City (TW)

(21) Appl. No.: 18/733,387

(22) Filed: Jun. 4, 2024

(51) Int. Cl. H01L 29/49; H01L 29/66; H01L 29/786

(52) U.S. Cl. CPC H10D 30/6739; H10D 30/6755; H10D 99/00

(57) ABSTRACT

A transistor structure may be formed in an interconnect layer of a semiconductor device. The transistor structure is formed such that a bottom high dielectric constant (high-k) terminal layer is included between a gate dielectric layer and an oxide-semiconductor channel layer of the transistor structure, and/or such that a top high-k terminal layer is included between the gate dielectric layer and a gate electrode of the transistor structure. The bottom high-k terminal layer may reduce the likelihood and/or magnitude of charge trapping that might otherwise occur at the interface between the gate dielectric layer and the gate electrode. The top high-k terminal layer may passivate loose bonds in the oxide-semiconductor channel layer, thereby reducing the likelihood and/or magnitude of charge trapping that might otherwise occur in the oxide-semiconductor channel layer.

### BACKGROUND

In some cases, a transistor may be formed in an interconnect layer of a semiconductor device. The interconnect layer is sometimes referred to as a backend region or back end of line (BEOL) region of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A and 2B is a diagram of an example implementation of a transistor structure described herein.

FIGS. 3A-3F are diagrams of an example implementation of forming the semiconductor device described herein.

FIGS. 4A-4H are diagrams of an example implementation of forming the transistor structure described herein.

FIG. 5 is a diagram of an example implementation of a transistor structure described herein.

FIGS. 6A-6D are diagrams of an example implementation of forming the transistor structure described herein.

FIG. 7 is a diagram of an example implementation of a transistor structure described herein.

FIG. 8 is a diagram of an example implementation of a transistor structure described herein.

FIGS. 9A-9E are diagrams of example implementations of a transistor structure described herein.

FIG. 10 is a diagram of an example implementation of a transistor structure described herein.

FIG. 11 is a flowchart of an example process associated with forming a semiconductor device described herein.

FIG. 12 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Forming a transistor in an interconnect layer (e.g., a back end of line (BEOL) region or backend region) of a semiconductor device often involves the use of different materials and/or structures than those used in transistors formed in a device layer (e.g., a front end of line (FEOL) region) of the semiconductor device. The transistors in the device layer can be formed in a semiconductor substrate of the semiconductor device, whereas transistors formed in the interconnect layer of the semiconductor device are typically formed in a dielectric layer in the semiconductor device. Thus, oxide-semiconductor materials are often used in the channel layers of the transistors in the interconnect layer because oxide-semiconductor materials offer better integration with the dielectric materials used in the interconnect layer compared to semiconductor materials used in the channel layers of the transistors in the device layer. In particular, oxide-semiconductor materials may be processed at lower temperatures, may achieve greater nucleation uniformity on dielectric materials, and/or may achieve higher crystallinity (and thus, higher charge carrier mobility and lower off current (I_{off})) on dielectric materials than semiconductor materials such as silicon (Si).

High dielectric constant (high-k) dielectric materials such has hafnium oxide (HfO₂) may be used for a gate dielectric layer between an oxide-semiconductor channel and a gate electrode of a transistor. High-k dielectric materials have higher dielectric constants, enabling the gate dielectric layer to be formed thinner while achieving sufficiently low gate leakage and increased gate control in the transistor. However, such high-k dielectric materials are often times susceptible to charge trapping. Charge trapping in the gate dielectric layer can lead to slower switching times and increased hysteresis in the operation of the transistor. Moreover, such high-k dielectric materials may cause oxygen vacancies to be formed in the oxide-semiconductor channel when the oxide-semiconductor channel is formed on the gate dielectric layer, leading to the formation of current leakage paths in the oxide-semiconductor channel.

In some implementations described herein, a transistor structure may be formed in an interconnect layer (e.g., a backend region or BEOL region) of a semiconductor device. The transistor structure is formed such that a bottom high-k terminal layer is included between a gate dielectric layer and an oxide-semiconductor channel layer of the transistor structure, and/or such that a top high-k terminal layer is included between the gate dielectric layer and a gate electrode of the transistor structure. The bottom high-k terminal layer includes one or more materials that promote oxygen-to-metal bonding between the gate dielectric layer and the gate electrode, thereby reducing the likelihood and/or magnitude of charge trapping that might otherwise occur at the interface between the gate dielectric layer and the gate electrode. The top high-k terminal layer also promotes oxygen-to-metal bonding between the gate dielectric layer and oxide-semiconductor channel layer, which passivates loose bonds in the oxide-semiconductor channel layer, thereby reducing the likelihood and/or magnitude of charge trapping that might otherwise occur in the oxide-semiconductor channel layer. In this way, the high-k terminal layers may enable faster switching speeds and/or lesser current leakage to be achieved for the transistor structure.

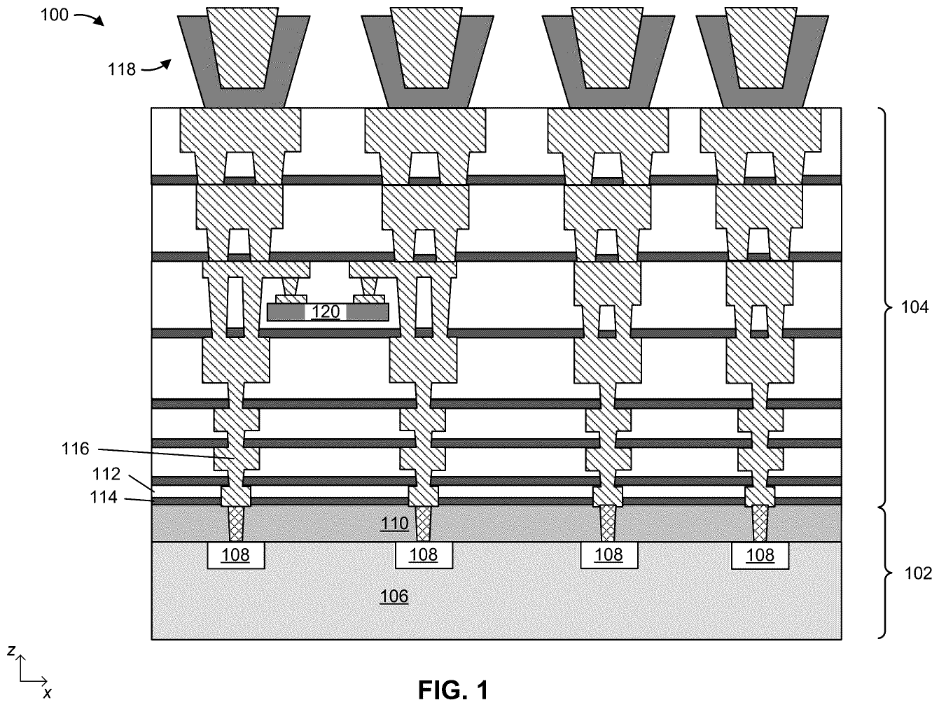

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), and/or another type of semiconductor device.

As shown in FIG. 1, the semiconductor device 100 may include a device layer 102 and an interconnect layer 104 above the device layer 102 in a z-direction in the semiconductor device 100. The device layer 102 may also be referred to as a frontend region or FEOL region of the semiconductor device 100. The interconnect layer 104 may also be referred to as a backend region or BEOL region of the semiconductor device 100.

The device layer 102 includes a substrate 106. The substrate 106 may correspond to a portion of a semiconductor wafer on which the semiconductor device 100 is formed. The substrate 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 106 may extend in an x-direction and/or in a y-direction in the semiconductor device 100.

Semiconductor devices 108 may be included in and/or on the substrate 106 in the device layer 102 of the semiconductor device 100. The semiconductor devices 108 include frontend transistor structures (e.g., frontend planar transistor structures, frontend fin field effect transistor (finFET) structures, frontend gate all around (GAA) transistor structures), pixel sensors, capacitors, resistors, inductors, photodetectors, transceivers, transmitters, receives, optical circuits, and/or other types of frontend semiconductor devices. Frontend semiconductor devices refer to the semiconductor devices that are formed in the device layer 102 (e.g., in and/or on the substrate 106) of the semiconductor device 100.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the semiconductor devices 108 to be selectively etched or protected from etching, and/or to electrically isolate the semiconductor devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in a y-direction in the semiconductor device 100.

The interconnect layer 104 of the semiconductor device 100 is included above the substrate 106 and above the semiconductor devices 108 in the z-direction in the semiconductor device 100. The interconnect layer 104 includes a plurality of dielectric layers (e.g., backend dielectric layers) that are arranged in a direction (e.g., the z-direction) that is approximately perpendicular to the substrate 106. The dielectric layers may include ILD layers 112 and ESLs 114 that are arranged in an alternating manner in the z-direction. The ILD layers 112 and the ESLs 114 may extend in the x-direction and/or in the y-direction in the semiconductor device 100.

The ILD layers 112 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 112 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 114 may each include a silicon nitride (SiₓN_{y}), silicon carbide (SiC), silicon oxynitride (SiON), and/or another suitable dielectric material. In some implementations, an ILD layer 112 and an ESL 114 include different dielectric materials to provide etch selectivity to enable various structures to be formed in the interconnect layer 104.

The interconnect layer 104 includes a plurality of conductive structures 116. One or more of the conductive structures 116 are electrically coupled and/or physically coupled with one or more of the semiconductor devices 108 in the device layer 102. The conductive structures 116 provide electrical routing that enables signals and/or power to be provided to and/or from the semiconductor devices 108. The conductive structures 116 may include a combination of vias, trenches, contacts, plugs, interconnects, metallization layers, conductive traces, and/or other types of conductive structures. The conductive structures 116 may one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the conductive structures 116 and the ILD layers 112, and/or between the conductive structures 116 and the ESLs 114. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures 116 of the interconnect layer 104 may be arranged in in a vertical manner (e.g., in the z-direction). In other words, a plurality of stacked conductive structures 116 extend between the device layer 102 and connection structures 118 above the interconnect layer 104 to facilitate electrical signals and/or power to be routed between the device layer 102 and the connection structures 118. The plurality of stacked conductive structures 116 may be referred to as M-layers. For example, a metal-0 (M0) layer may located at the bottom of the interconnect layer 104 and may be directly coupled with the device layer 102 (e.g., with the contacts or vias of the semiconductor devices 108 in the device layer 102), a metal-1 layer (M1) layer may be located above the M0 layer in the interconnect layer 104, a metal-2 layer (M2) layer may be located above the M1 layer, and so on. Additionally, via layers may be included between vertically arranged M-layers. For example, a via-1 (V1) layer may be included between the M1 layer and the M2 layer to interconnect the M1 layer and the M2 layer, a via-2 (V2) layer may be included between the M2 layer and the M3 layer to interconnect the M2 layer and the M3 layer, and so on.

The connection structures 118 include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. The connection structures 118 enable the semiconductor device 100 to be attached to a semiconductor device package substrate (e.g., an interposer, a redistribution layer (RDL) structure, a printed circuit board (PCB)) and/or to another semiconductor device.

One or more semiconductor devices are also included in the interconnect layer 104 of the semiconductor device 100. For example, a transistor structure 120 is included in an ILD layer 112 of the interconnect layer 104. The transistor structure 120 may be referred to as a backend transistor structure or BEOL transistor structure in that the transistor structure 120 is included in the interconnect layer 104 (e.g., the backend region or BEOL region) of the semiconductor device 100 as opposed to the device layer 102 (e.g., the frontend region or FEOL region) of the semiconductor device 100. The transistor structure 120 is electrically coupled and/or physically coupled with one or more conductive structures 116 in the interconnect layer 104.

In some implementations, the transistor structure 120 may be electrically coupled to a capacitor in the interconnect layer 104. The combination of the transistor structure 120 and the capacitor may correspond to a memory cell (e.g., a dynamic random access memory (DRAM) cell) in the interconnect layer 104. In some implementations, the transistor structure 120 includes a memory layer (e.g., a ferroelectric memory layer, a resistive memory layer, a floating memory layer) such that the transistor structure 120 corresponds to a transistor-based memory cell (e.g., a ferroelectric field effect transistor (FeFET) memory cell, floating gate transistor memory cell).

As indicated above, FIG. 1 is provided as an example. Other examples may differ from what is described with regard to FIG. 1.

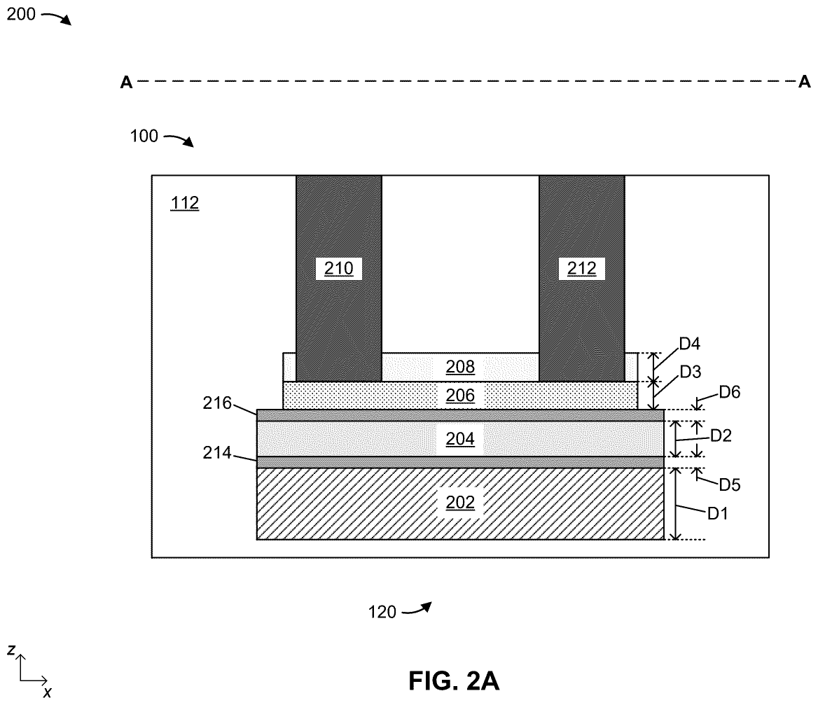

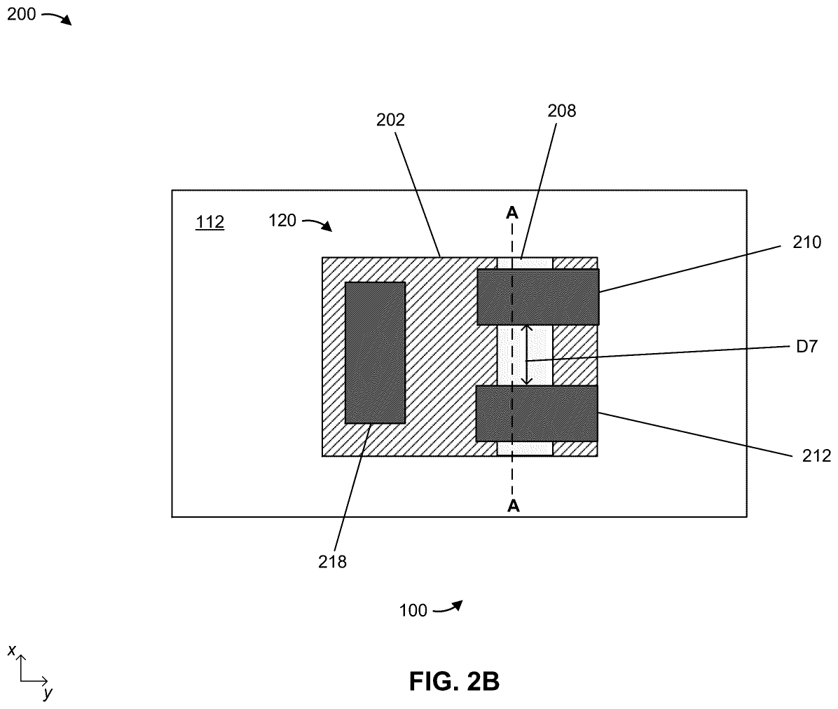

FIGS. 2A and 2B is a diagram of an example implementation 200 of a transistor structure 120 described herein. As described in connection with FIG. 1, the transistor structure 120 may be referred to as a backend transistor structure or a BEOL transistor structure that that the transistor structure 120 is included in an ILD layer 112 in the interconnect layer 104 of the semiconductor device 100. The transistor structure 120 may also be referred to as a thin-film transistor (TFT) in that one or more layers (e.g., a gate dielectric layer, a channel layer) of the transistor structure 120 are formed as thin films using thin-film deposition techniques. The transistor structure 120 includes an oxide-semiconductor channel layer, which enables the manufacturing process for the transistor structure 120 to be integrated into the manufacturing process for the interconnect layer 104.

FIG. 2A illustrates a cross-section view of the transistor structure 120. The transistor structure 120 may include a gate electrode 202. The gate electrode 202 may be referred to as a bottom gate electrode or a buried gate electrode in that the gate electrode 202 is located at the bottom of the transistor structure 120. The gate electrode 202 may be electrically coupled with a gate contact, as shown in FIG. 2B. The gate electrode 202 may include one or more electrically conductive metal materials. Examples of such electrically conductive metal-containing materials include platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), palladium (Pd), copper (Cu), aluminum (Al), ruthenium (Ru), and/or an alloy thereof, among other examples. In some implementations, a z-direction thickness of the gate electrode 202 (indicated in FIG. 2A as a dimension D1) is included in a range of approximately 50 angstroms to approximately 500 angstroms. However, other values and/or ranges for the z-direction thickness of the gate electrode 202 are within the scope of the present disclosure.

The transistor structure 120 includes a gate dielectric layer 204. The gate dielectric layer 204 may be included over and/or on the gate electrode 202. The gate dielectric layer 204 may be a high-k gate dielectric layer in that the gate dielectric layer 204 may include one or more high-k dielectric materials that have a dielectric constant greater than the dielectric constant of silicon dioxide (SiO₂—approximately 3.9 dielectric constant). Examples of such high-k dielectric materials include metal-oxide materials having a dielectric constant that is greater than or approximately equal to 9, such as hafnium oxide (HfOₓ such as HfO₂), aluminum oxide (AlₓO_{y} such as Al₂O₃), and/or zirconium oxide (ZrOₓ such as ZrO₂), among other examples. In some implementations, the gate dielectric layer 204 includes an oxide-containing dielectric material having a dielectric constant that is greater than or approximately equal to 6. For example, the gate dielectric layer 204 may include an oxide material that includes two or more of hafnium (Hf), titanium (Ti), lanthanum (La), silicon (Si), and/or zirconium (Zr). Examples of such dielectric materials include hafnium titanium oxide (HfₓTi_{y}O_{z}), hafnium lanthanum oxide (HfₓLa_{y}O_{z}), hafnium silicon oxide (HfₓSi_{y}O_{z}), and/or hafnium zirconium oxide (HfₓZr_{y}O_{z}), among other examples. Additionally and/or alternatively, the gate dielectric layer 204 may include a silicon oxide (SiOₓ such as SiO₂) and/or a low-k dielectric layer.

The gate dielectric layer 204 may include a thin-film layer having a z-direction thickness (indicated in FIG. 2A as a dimension D2) that is included in a range of approximately 30 angstroms to approximately 150 angstroms. However, other values and/or ranges for the z-direction thickness of the gate dielectric layer 204 are within the scope of the present disclosure.

In some implementations, the gate dielectric layer 204 may function as a memory layer of the transistor structure 120. For example, the gate dielectric layer 204 may include a ferroelectric material for which an electric polarization can be switched between two or more discrete polarization states by applying an external electric field to the gate dielectric layer 204. The polarization states correspond to different values for data stored in the transistor structure 120. Examples of such ferroelectric materials include aluminum scandium nitride (e.g., AlScN), PBT (e.g., PbZrO₃), PZT (e.g., Pb[ZrₓTi₁₋ₓ]O₃, (0≤x≤1)), PLZT (e.g., Pb₁₋ₓLaₓZr_{1-y}Ti_{y}O₃), barium titanate (e.g., BaTiO₃), lead titanate (e.g., PbTiO₃), lead metaniobate (e.g., PbNb₂O₆), lithium niobate (e.g., LiNbO₃), lithium tantalate (e.g., LiTaO₃), PMN (e.g., PbMg₁₋₃Nb_{2/3}O₃), PST (e.g., PbSc_{1/2}Ta_{1/2}O₃), SBT (e.g., SrBi₂Ta₂O₉), BNT (e.g., Bi_{1/2}Na_{1/2}TiO₃), and/or combinations thereof, among other examples. In some implementations, the ferroelectric material may include dopants such as scandium (Sc), lanthanum (La), calcium (Ca), barium (Ba), yttrium (Y), strontium (Sr), zirconium (Zr), silicon (Si), aluminum (Al), scandium (Sc), indium (In), and/or gadolinium (Gd), among other examples. For example, the ferroelectric material may include hafnium oxide doped with zirconium (e.g., Zr:HfO₂), hafnium oxide doped with silicon (e.g., Si:HfO₂), hafnium oxide doped with lanthanum (e.g., La:HfO₂), hafnium oxide doped with aluminum (e.g., Al:HfO₂), hafnium oxide doped with tantalum (Ta:HfO₂), hafnium oxide doped with scandium (e.g., Sc:HfO₂), hafnium oxide doped with yttrium (e.g., Y:HfO₂), hafnium oxide doped with strontium (e.g., Sr:HfO₂), hafnium oxide doped with indium (e.g., In:HfO₂), and/or hafnium oxide doped with gadolinium (e.g., Gd:HfO₂), among other examples.

The transistor structure 120 includes an oxide-semiconductor channel layer 206 above the gate dielectric layer 204. In some implementations, a capping layer 208 may be included on the oxide-semiconductor channel layer 206 or may be omitted. The oxide-semiconductor channel layer 206 includes one or more oxide-semiconductor materials. Examples of such oxide-semiconductor materials such as tin oxide (e.g., SnO or SnO₂), indium gallium zinc oxide (InGaZnO or IGZO), indium gallium oxide (InGaO or IGO), indium zinc oxide (InZnO or IZO), indium tungsten oxide (InWO or IWO), among other examples. In some implementations, the oxide-semiconductor channel layer 206 includes an oxide-semiconductor material that includes indium (In), gallium (Ga), zinc (Zn), and one or more additional metals such as titanium (Ti), aluminum (Al), silver (Ag), vanadium (V), scandium (Sc), tungsten (W), tin (Sn), cerium (Ce), among other examples. For example, the oxide-semiconductor channel layer 206 may include InₓGa_{y}Zn_{z}MO, where M corresponds to one or more of the above-described metals, where 0≤x≤1, where 0≤y≤1, and where 0≤z≤1.

The electrical conductivity of the oxide-semiconductor channel layer 206 is capable of being selectively controlled by the gate electrode 202 to selectively enable an electrical current to flow between source/drain electrodes 210 and 212 of the transistor structure 120. When a voltage is applied to the gate electrode 202, the oxide-semiconductor channel layer 206 may become electrically conductive, thereby enabling the electrical current to flow between source/drain electrodes 210 and 212. Conversely, when the voltage is removed from the gate electrode 202, the oxide-semiconductor channel layer 206 may become electrically non-conductive, thereby preventing the electrical current from flowing between source/drain electrodes 210 and 212.

The oxide-semiconductor channel layer 206 may be a thin-film layer having a z-direction thickness (indicated in FIG. 2A as a dimension D3) that is included in a range of approximately 30 angstroms to approximately 200 angstroms. However, other values and/or ranges for the z-direction thickness of the oxide-semiconductor channel layer 206 are within the scope of the present disclosure. The capping layer 208 may be thin-film layer having a z-direction thickness (indicated in FIG. 2A as a dimension D4) that is included in a range of approximately 10 angstroms to approximately 200 angstroms. However, other values and/or ranges for the z-direction thickness of the capping layer 208 are within the scope of the present disclosure. The capping layer 208 may include one or more dielectric materials, such as silicon oxide (SiOₓ such as SiO₂), hafnium oxide (HfOₓ such as HfO₂), aluminum oxide (AlₓO_{y} such as Al₂O₃), titanium oxide (TiOₓ such as TiO₂), and/or another suitable dielectric material.

The source/drain electrodes 210 and 212 may be included above and/or on the oxide-semiconductor channel layer 206. The source/drain electrodes 210 and 212 may be in direct physical contact with the oxide-semiconductor channel layer 206, or one or more layers (e.g., liners, barrier layers, adhesion layers) may be included between the oxide-semiconductor channel layer 206 and the source/drain electrodes 210 and 212. A source/drain electrode may refer to a source region or a drain electrode, individually or collectively, dependent upon the context. The source/drain electrodes 210 and 212 may each include one or more electrically conductive materials, such one or more metals and/or one or more metal-containing materials, among other examples. Examples of such materials include platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), palladium (Pd), copper (Cu), aluminum (Al), ruthenium (Ru), and/or an alloy thereof, among other examples. In some implementations, the z-direction thickness of each of the source/drain electrodes 210 and 212 is included in a range of approximately 50 angstroms to approximately 500 angstroms. In some implementations, the z-direction thickness of each of the source/drain electrodes 210 and 212 is greater than approximately 5 nanometers. However, other values and/or ranges for the z-direction thickness of each of the source/drain electrodes 210 and 212 are within the scope of the present disclosure.

The source/drain electrodes 210 and 212 may each be electrically coupled with a conductive structure 116 in the interconnect layer 104 of the semiconductor device 100. This enables electrical inputs (e.g., voltages, electrical currents) to be applied to the source/drain electrode 210 and/or the source/drain electrode 212, and/or enables the source/drain electrode 210 and/or the source/drain electrode 212 to be electrically grounded. Additionally and/or alternatively, the source/drain electrode 210 and/or 212 may be electrically coupled with a capacitor structure through one or more conductive structures 116 in the interconnect layer 104.

As further shown in FIG. 2A, the transistor structure 120 may further include one or more high-k terminal layers above and/or below the gate dielectric layer 204. For example, a bottom high-k terminal layer 214 may be included under the gate dielectric layer 204 such that the bottom high-k terminal layer 214 is between the gate electrode 202 and the gate dielectric layer 204. As another example, a top high-k terminal layer 216 may be included on the gate dielectric layer 204 such that the top high-k terminal layer 216 is between the gate dielectric layer 204 and the oxide-semiconductor channel layer 206.

The bottom high-k terminal layer 214 may be included between the gate electrode 202 and the gate dielectric layer 204 to passivate the surface of the gate electrode 202 to prevent or reduce the likelihood formation of native oxides on the gate electrode 202 that might otherwise form due to oxidation of the surface of the gate electrode 202. Additionally and/or alternatively, the bottom high-k terminal layer 214 may be included between the gate electrode 202 and the gate dielectric layer 204 to promote and/or enhance the bonding strength between the gate electrode 202 and the gate dielectric layer 204. The passivation of the surface of the gate electrode 202 and/or the enhanced bonding strength provided by the bottom high-k terminal layer 214 may reduce the likelihood and/or magnitude of charge trapping that might otherwise occur at the interface between the gate dielectric layer 204 and the gate electrode 202.

To provide enhanced bonding strength between the gate electrode 202 and the gate dielectric layer 204, the bottom high-k terminal layer 214 may include one or more high-k materials that have a higher metal-to-oxygen bonding strength (e.g., in kilo Joules per mol (kJ/mol)) than the metal-to-oxygen bonding strength of the high-k dielectric material of the gate dielectric layer 204. The high oxygen-metal bonding strength of the bottom high-k terminal layer 214 promotes and/or enhances bonding between oxygen in the high-k material(s) of the bottom high-k terminal layer 214 and the metal material of the gate electrode 202. Examples of high-k materials that may be included in the bottom high-k terminal layer 214 include high-k dielectric materials such as an aluminum oxide (AlₓO_{y} such as Al₂O₃) material, an yttrium oxide (YₓO_{y} such as Y₂O₃) material, a samarium oxide (SmₓO_{y} such as Sm₂O₃) material, a gadolinium oxide (GdₓO_{y} such as Gd₂O₃) material, a scandium oxide (ScₓO_{y} such as Sc₂O₃) material, an ytterbium oxide (YbₓO_{y} such as Yb₂O₃) material, and/or a lutetium oxide (LuₓO_{y} such as Lu₂O₃) material, among other examples. In some implementations, the high-k material of the bottom high-k terminal layer 214 is different from the high-k dielectric material of the gate dielectric layer 204.

The high-k material of the bottom high-k terminal layer 214 may also have a sufficiently high band gap (e.g., greater than approximately 5 electron volts (eV), among other examples) such that the bottom high-k terminal layer 214 provides a sufficient charge-injection barrier so as to not contribute (or minimally contributes) to gate leakage in the transistor structure 120. In some implementations, the high-k material of the bottom high-k terminal layer 214 has a band gap that is approximately equal to or greater than the band gap of the gate dielectric layer 204.

Moreover, the high-k material of the bottom high-k terminal layer 214 may also have a sufficiently high dielectric constant (e.g., a dielectric constant greater than approximately 10) to enable a sufficiently low subthreshold voltage swing to be achieved for the transistor structure 120, to enable a sufficiently high gate voltage (e.g., gate threshold voltage) to be achieved for the transistor structure 120, and/or to achieve a sufficiently high equivalent oxide thickness (EOT) for the gate dielectric layer 204, among other examples. In some implementations, the dielectric constant of the high-k material of the bottom high-k terminal layer 214 and the dielectric constant of the high-k dielectric material of the gate dielectric layer 204 are approximately equal (e.g., with 5% of each other, with 1% of each other). In some implementations, the dielectric constant of the high-k material of the bottom high-k terminal layer 214 is greater than the dielectric constant of the high-k dielectric material of the gate dielectric layer 204. In some implementations, the dielectric constant of the high-k dielectric material of the gate dielectric layer 204 is greater than the dielectric constant of the high-k material of the bottom high-k terminal layer 214.

In some implementations, the bottom high-k terminal layer 214 may be a thin-film layer having a z-direction thickness (indicated in FIG. 2A as a dimension D5) that is included in a range of approximately 1 angstrom to approximately 20 angstroms. If the z-direction thickness of the bottom high-k terminal layer 214 is greater than approximately 20 angstroms, the bottom high-k terminal layer 214 may degrade the performance of the gate dielectric layer 204, resulting in decreased EOT for the gate dielectric layer 204, increase charge-trapping, and/or increased voltage drop, among other examples. However, other values and ranges for the thickness of the bottom high-k terminal layer 214 are within the scope of the present disclosure. In some implementations, the bottom high-k terminal layer 214 may formed as a discontinuous film having a thickness of approximately 1 angstrom or less.

The top high-k terminal layer 216 may be included between the gate dielectric layer 204 and the oxide-semiconductor channel layer 206 to passivate loose bonds in the oxide-semiconductor channel layer 206. Thus, the top high-k terminal layer 216 functions as a buffer layer that reduces the likelihood of loose bonds in the oxide-semiconductor channel layer 206 interacting with gate dielectric layer 204, which reduces the likelihood and/or magnitude of charge trapping that might otherwise occur in the oxide-semiconductor channel layer 206. Additionally and/or alternatively, the top high-k terminal layer 216 may be included between the gate dielectric layer 204 and the oxide-semiconductor channel layer 206 to promote and/or enhance the bonding strength between the gate dielectric layer 204 and the oxide-semiconductor channel layer 206.

To provide enhanced bonding strength between the gate dielectric layer 204 and the oxide-semiconductor channel layer 206, the top high-k terminal layer 216 may include one or more high-k materials that have a similar (e.g., approximately equal) metal-to-oxygen bonding strengths (e.g., in kJ/mol) as the metal-to-oxygen bonding strength of the oxide-semiconductor material of the oxide-semiconductor channel layer 206. For example, the metal-to-oxygen bonding strength of the top high-k terminal layer 216 and the metal-to-oxygen bonding strength of the oxide-semiconductor channel layer 206 may be within approximately 1% of each other. As another example, the metal-to-oxygen bonding strength of the top high-k terminal layer 216 and the metal-to-oxygen bonding strength of the oxide-semiconductor channel layer 206 may be within approximately 5% of each other. The similar metal-to-oxygen bonding strengths of the top high-k terminal layer 216 and the oxide-semiconductor channel layer 206 promotes metal-to-oxygen bonding between the top high-k terminal layer 216 and oxide-semiconductor channel layer 206. Examples of high-k materials that may be included in the top high-k terminal layer 216 include high-k dielectric materials such as a hafnium oxide (HfOₓ such as HfO₂) material, a zirconium oxide (ZrOₓ such as ZrO₂) material, a titanium oxide (TiOₓ such as TiO₂) material, a magnesium oxide (MgO) material, a calcium oxide (CaO) material, or a hafnium zirconium oxide (HfₓZr_{y}O_{z}) material, among other examples. In some implementations, the high-k material of the top high-k terminal layer 216 is different from the high-k dielectric material of the gate dielectric layer 204.

The high-k material of the top high-k terminal layer 216 may also have a sufficiently high band gap (e.g., greater than approximately 5 eV, among other examples) such that the top high-k terminal layer 216 provides a sufficient charge-injection barrier so as to not contribute (or minimally contributes) to gate leakage in the transistor structure 120. In some implementations, the high-k material of the top high-k terminal layer 216 has a band gap that is approximately equal to or greater than the band gap of the gate dielectric layer 204.

Moreover, the high-k material of the top high-k terminal layer 216 may also have a sufficiently high dielectric constant (e.g., a dielectric constant greater than approximately 10) to enable a sufficiently low subthreshold voltage swing to be achieved for the transistor structure 120, to enable a sufficiently high gate voltage (e.g., gate threshold voltage) to be achieved for the transistor structure 120, and/or to achieve a sufficiently high EOT for the gate dielectric layer 204, among other examples. In some implementations, the dielectric constant of the high-k material of the top high-k terminal layer 216 and the dielectric constant of the high-k dielectric material of the gate dielectric layer 204 are approximately equal (e.g., with 5% of each other, with 1% of each other). In some implementations, the dielectric constant of the high-k material of the top high-k terminal layer 216 is greater than the dielectric constant of the high-k dielectric material of the gate dielectric layer 204. In some implementations, the dielectric constant of the high-k dielectric material of the gate dielectric layer 204 is greater than the dielectric constant of the high-k material of the top high-k terminal layer 216.

In some implementations, the top high-k terminal layer 216 may be a thin-film layer having a z-direction thickness (indicated in FIG. 2A as a dimension D6) that is included in a range of approximately 1 angstrom to approximately 20 angstroms. If the z-direction thickness of the top high-k terminal layer 216 is greater than approximately 20 angstroms, the top high-k terminal layer 216 may degrade the performance of the gate dielectric layer 204, resulting in decreased EOT for the gate dielectric layer 204, increase charge-trapping, and/or increased voltage drop, among other examples. However, other values and ranges for the thickness of the top high-k terminal layer 216 are within the scope of the present disclosure.

FIG. 2B illustrates a top view of the transistor structure 120 and a location of the cross-section along line A-A in FIG. 2A. As shown in FIG. 2B, the source/drain electrodes 210 and 212 may extend laterally outward past the sides of the oxide-semiconductor channel layer 206 in the y-direction in the semiconductor device 100. Similarly, the gate electrode 202 may extend laterally outward past the sides of the oxide-semiconductor channel layer 206, as well as laterally outward past the source/drain electrodes 210 and 212, in the y-direction in the semiconductor device 100. This enables a gate contact 218 to be formed on the gate electrode 202.

As further shown in FIG. 2B, the source/drain electrodes 210 and 212 are spaced apart in the x-direction, enabling a conductive channel to be selectively formed between the source/drain electrodes 210 and 212 through the oxide-semiconductor channel layer 206. A distance between the source/drain electrodes 210 and 212 (indicated in FIG. 2B as dimension D7) corresponds to a gate length (L_{g}) of the transistor structure 120. In some implementations, the gate length may be included in a range of approximately 1 nanometer to approximately 100 nanometers. However, other values and ranges for the gate length are within the scope of the present disclosure.

As indicated above, FIGS. 2A and 2B are provided as an example. Other examples may differ from what is described with regard to FIGS. 2A and 2B.

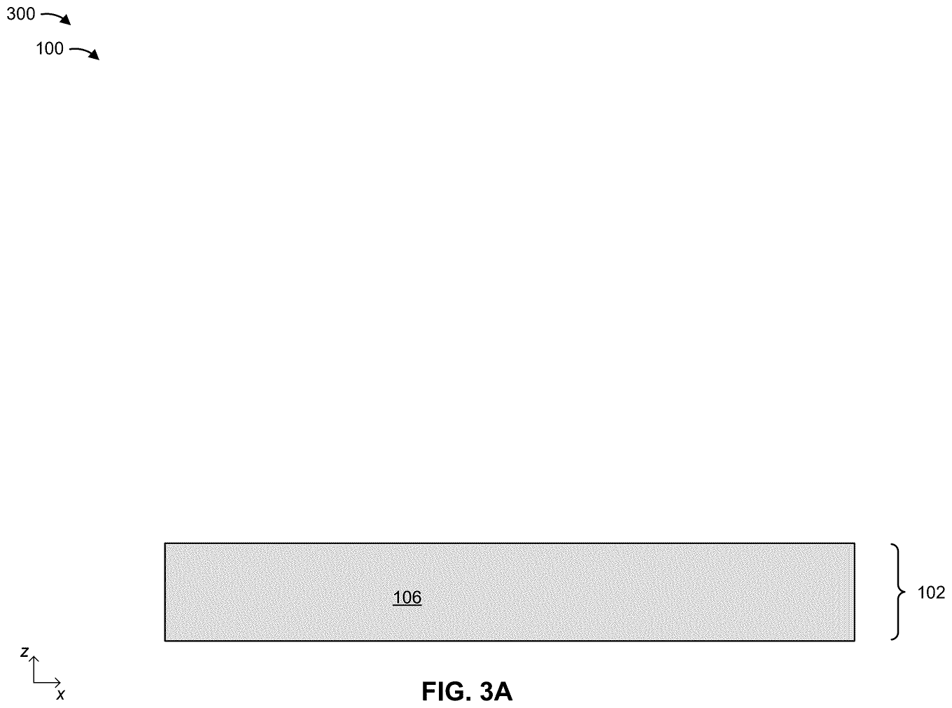

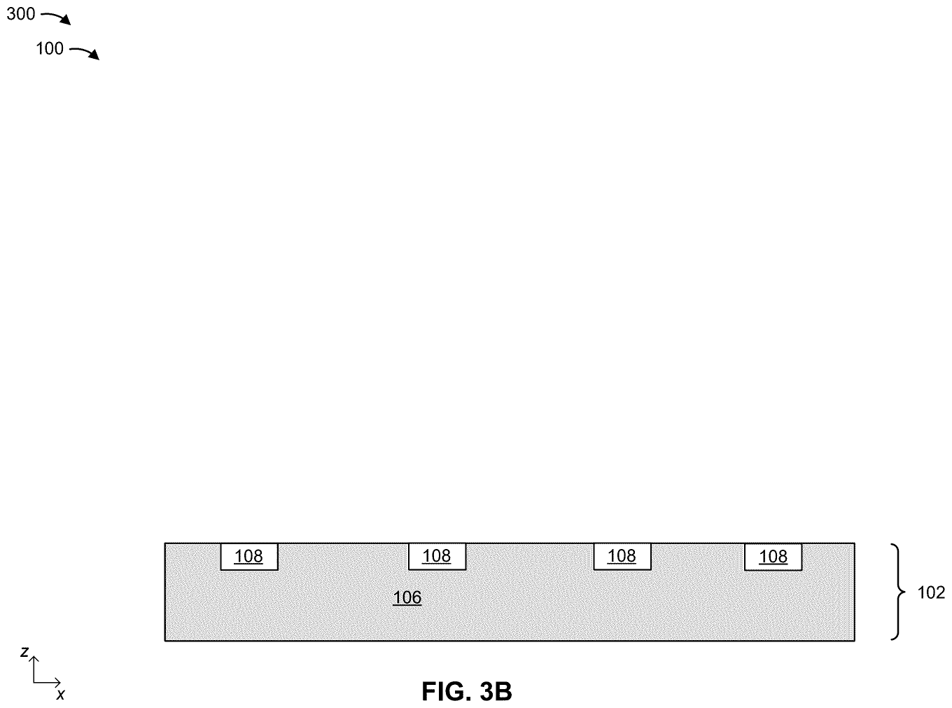

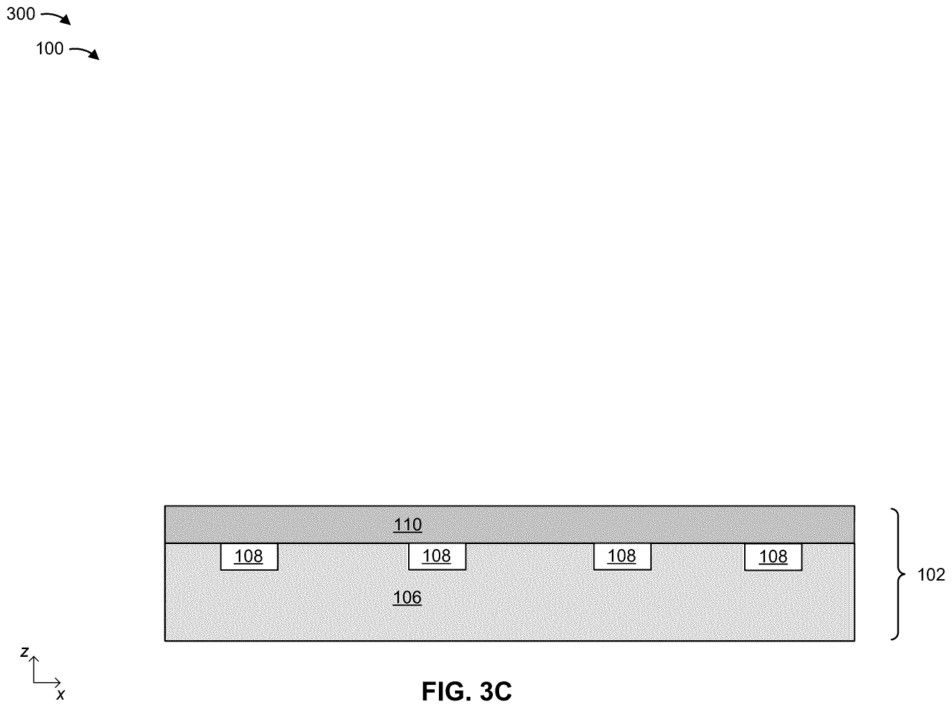

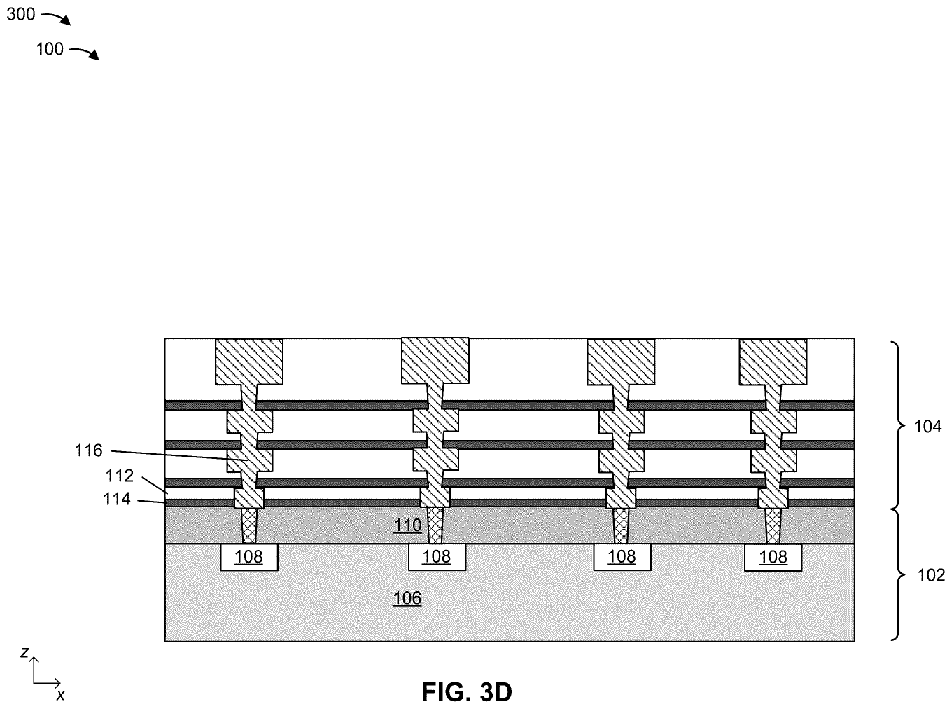

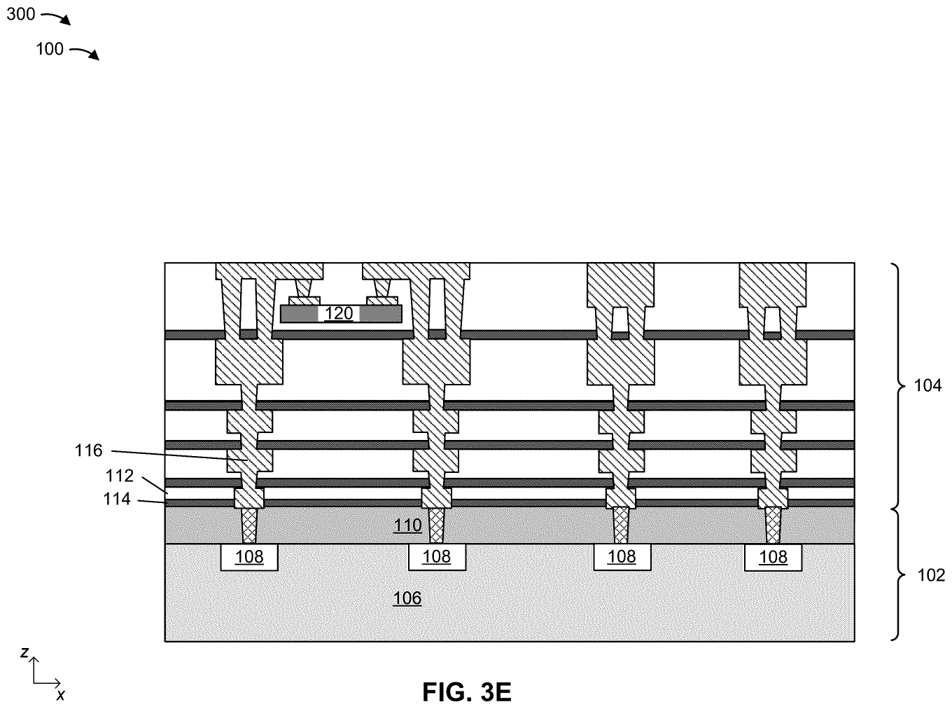

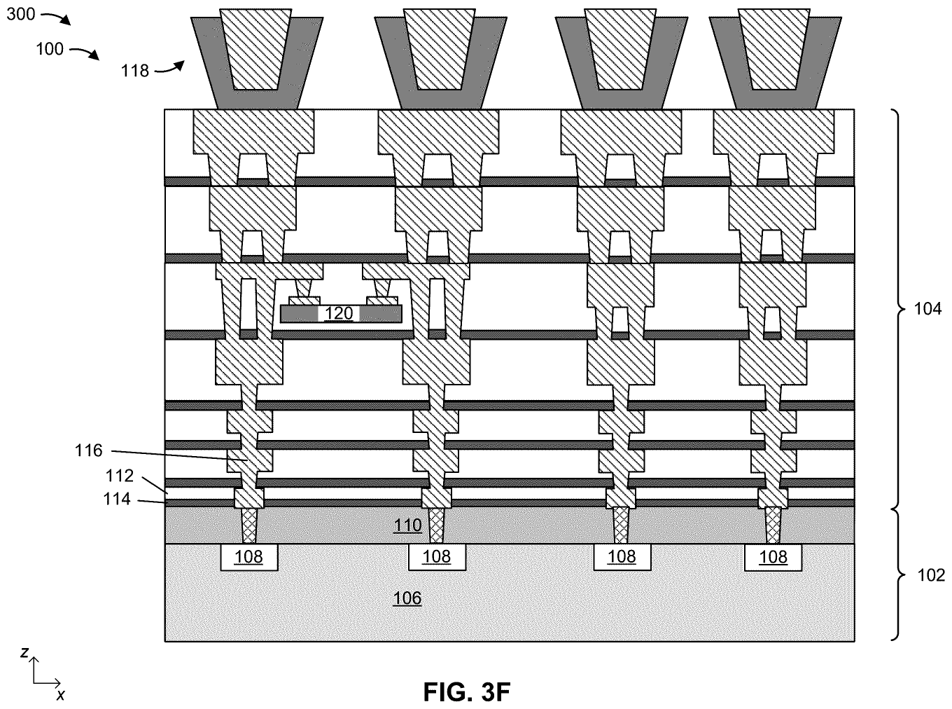

FIGS. 3A-3F are diagrams of an example implementation 300 of forming the semiconductor device 100 described herein. In some implementations, one or more of the semiconductor processing operations described in connection with FIGS. 3A-3F may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 3A, the substrate 106 is provided. The substrate 106 may be provided in the form of a semiconductor wafer such as a silicon (Si) wafer may be provided as an SOI wafer, and/or another type of semiconductor work piece.

As shown in FIG. 3B, the semiconductor devices 108 (e.g., the frontend semiconductor devices) may be formed in and/or on the substrate 106 in the device layer 102 of the semiconductor device 100. One or more semiconductor processing tools may be used to form one or more portions of the semiconductor devices 108. For example, a deposition tool may be used to perform various deposition operations to deposit layers and/or structures of the semiconductor devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the semiconductor devices 108. As another example, a planarization tool may be used to planarize portions of the semiconductor devices 108. As another example, a plating tool may be used to deposit metal structures and/or layers of the semiconductor devices 108.

As shown in FIG. 3C, a deposition tool is used to deposit the dielectric layer 110 over and/or on the substrate 106 and over and/or on the semiconductor devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to planarize the dielectric layer 110 after the dielectric layer 110 is deposited.

As shown in FIG. 3D, a first portion of the interconnect layer 104 of the semiconductor device 100 is formed above the dielectric layer 110. One or more deposition tools are used to deposit alternating layers of ILD layers 112 and ESLs 114 in the first portion of the interconnect layer 104 of the semiconductor device 100. In this way, the ILD layers 112 and ESLs 114 may be arranged in the z-direction in the semiconductor device 100. One or more deposition tools may be used to deposit each of the ILD layers 112 and each of the ESLs 114 using a PVD technique, an ALD technique, a CVD technique, an oxidation technique, and/or another suitable deposition technique. In some implementations, a planarization tool may be used to planarize the ILD layers 112 and/or the ESLs 114 after the ILD layers 112 and/or the ESLs 114 are deposited.

As further shown in FIG. 3D, a deposition tool, an exposure tool, a developer tool, an etch tool, a planarization tool, and/or a plating tool are used to perform various operations to form the conductive structures 116 in the first portion of the interconnect layer 104 of the semiconductor device 100. The conductive structures 116 may be included in the ILD layers 112 and/or the ESLs 114, and may be electrically coupled with the semiconductor devices 108 in the device layer 102. In some implementations, the ILD layers 112, the ESLs 114, and the conductive structures 116 may built up in the z-direction in metallization layers. For example, a first ESL 114 and a first ILD layer 112 may be formed, recesses may be formed in first ESL 114 and/or in the first ILD layer 112, and first conductive structures 116 (e.g., an M0 metallization layer) may be formed in the recesses. A second ESL 114 and a second ILD layer 112 may be formed above the first ESL 114 and the first ILD layer 112, recesses may be formed in second ESL 114 and/or in the second ILD layer 112, and second conductive structures 116 (e.g., an M1 metallization layer) may be formed in the recesses. The remaining metallization layers of the first portion of the interconnect layer 104 may be formed in a similar manner. Additionally, via layers may be formed to interconnect the metallization layers in the interconnect layer 104. The via layers may include conductive structures 116 corresponding to vias or interconnects that interconnect two or more metallization layers in the interconnect layer 104.

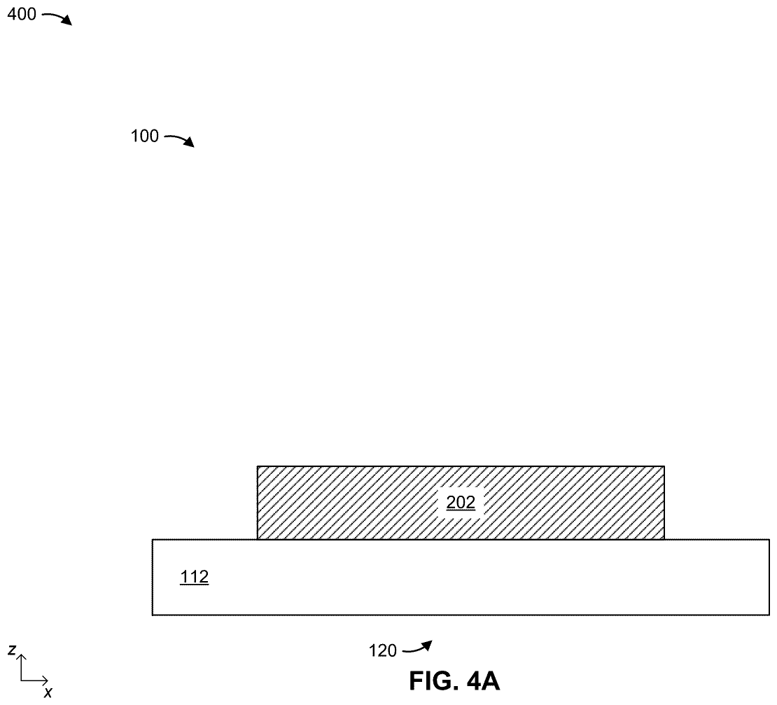

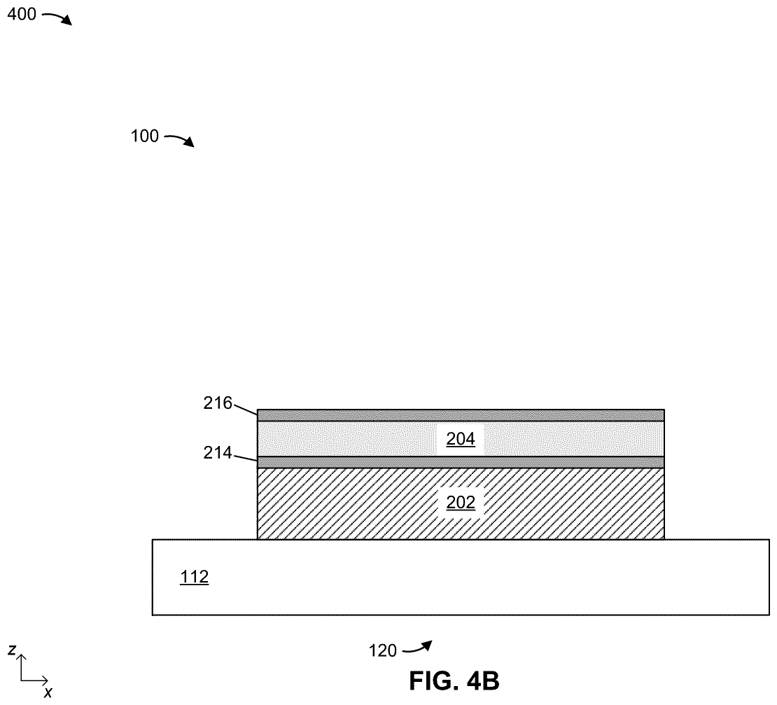

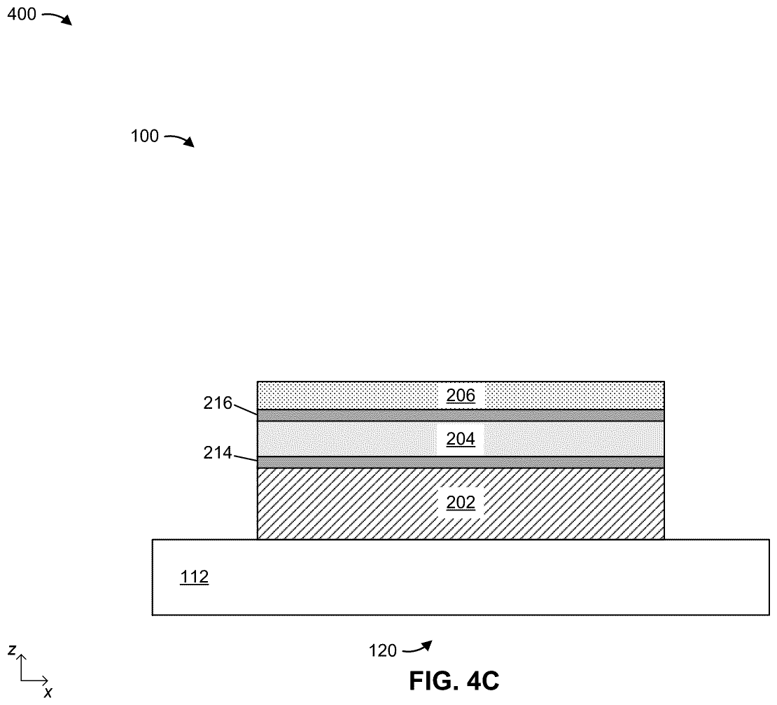

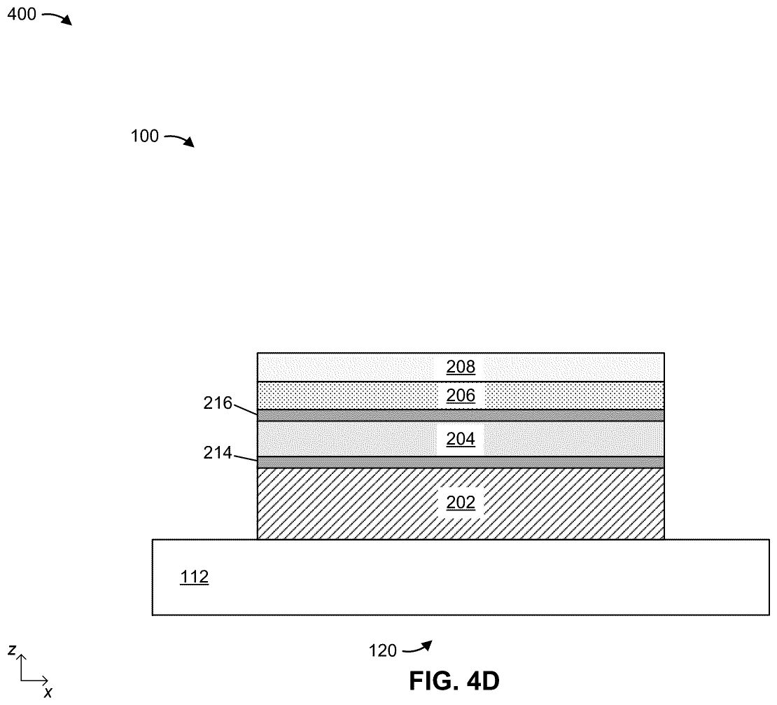

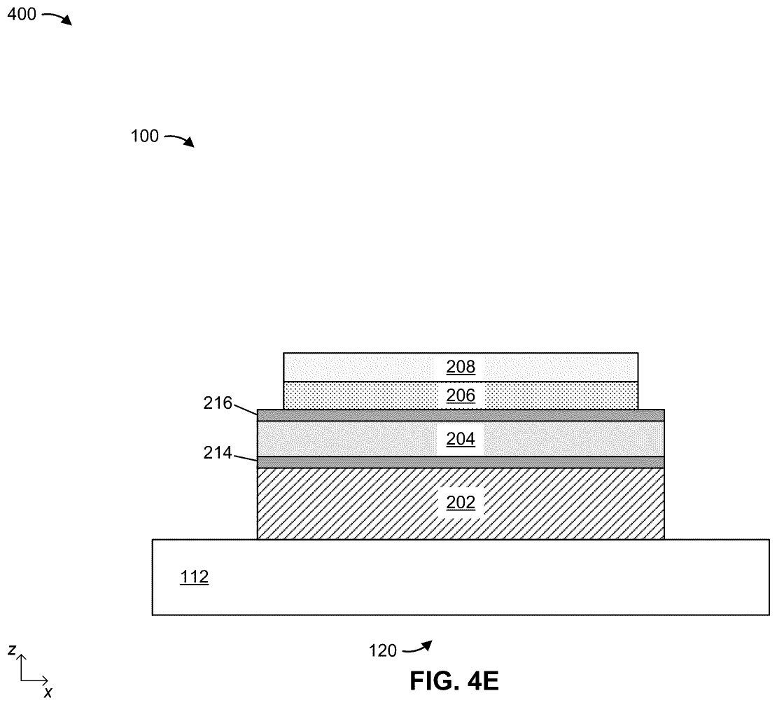

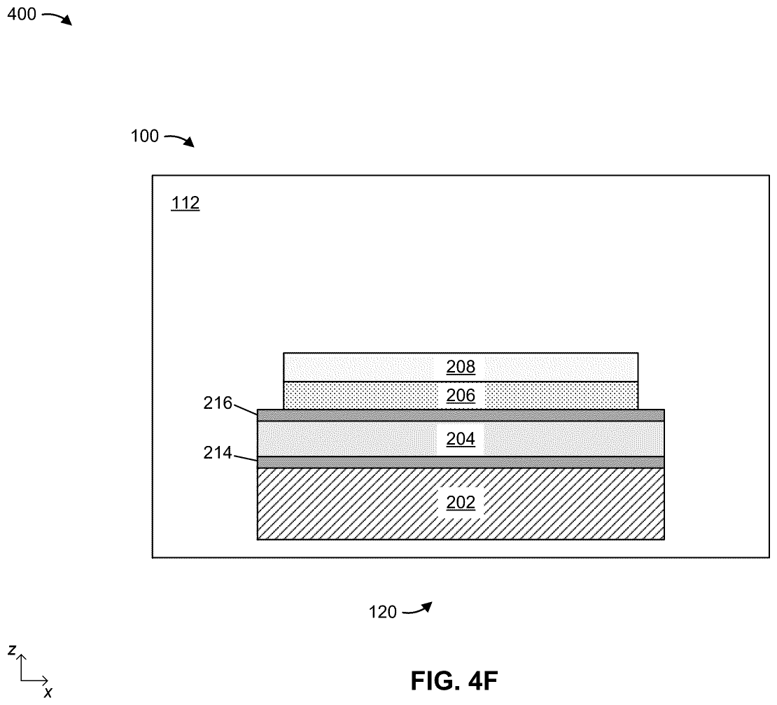

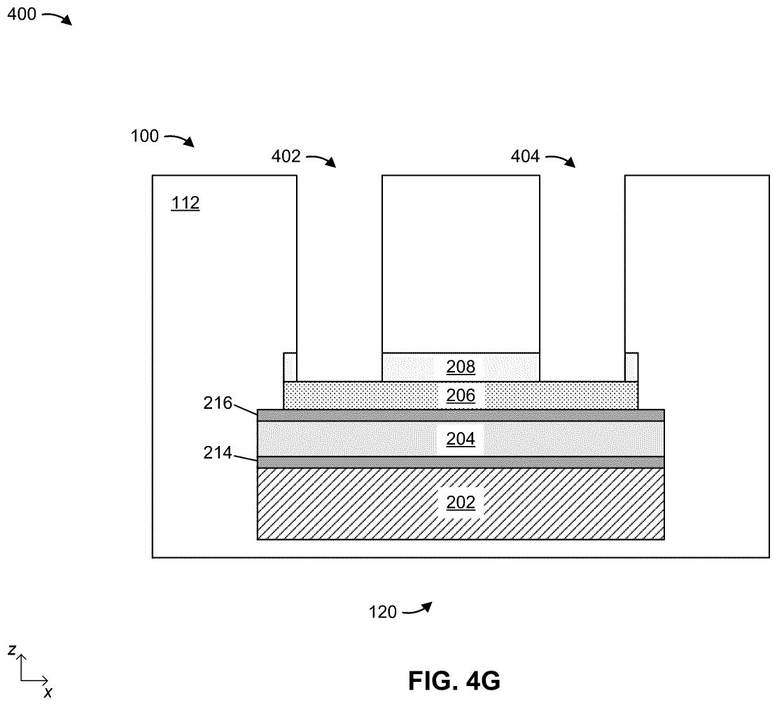

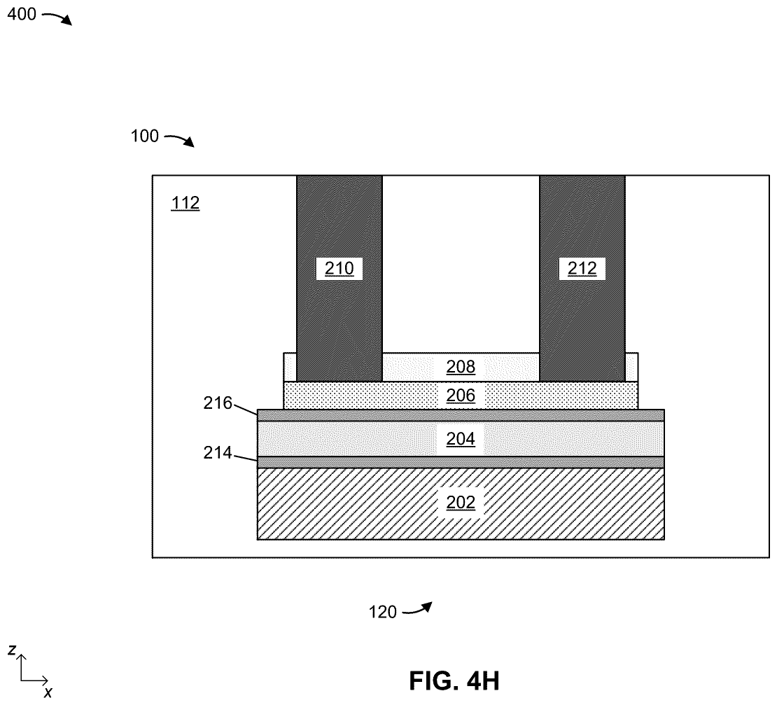

As shown in FIG. 3E, a second portion of the interconnect layer 104 of the semiconductor device 100 is formed over and/or on the first portion of the interconnect layer 104. Techniques similar to those described in connection with FIG. 3D may be performed to form the second portion of the interconnect layer 104. Additionally, a transistor structure 120 (e.g., a backend transistor structure or a BEOL transistor structure) is formed in an ILD layer 112 in the second portion of the interconnect layer 104. Conductive structures 116 may be formed on the transistor structure 120 to electrically connect the transistor structure 120 in the interconnect layer 104. An example implementation of forming the transistor structure 120 is illustrated and described in connection with FIGS. 4A-4H.

As shown in FIG. 3F, a third portion of the interconnect layer 104 may be formed above the second portion of the interconnect layer 104 that includes the transistor structure 120. The third portion of the interconnect layer 104 may be formed using a similar combination of techniques as described in connection with FIGS. 3D and 3E.

As further shown in FIG. 3F, the connection structures 118 are formed on the interconnect layer 104 such that the connection structures 118 are electrically coupled and/or physically coupled with one or more conductive structures 116 in the interconnect layer 104. A deposition tool may be used to deposit the connection structures 118 using a CVD technique, a PVD technique, an ALD technique, an electroplating technique, and/or a deposition technique other than as described above in connection with FIG. 1. In some implementations, a semiconductor packaging tool attaches the connection structures 118 to the semiconductor device 100.

As indicated above, FIGS. 3A-3F are provided as an example. Other examples may differ from what is described with regard to FIGS. 3A-3F.

FIGS. 4A-4H are diagrams of an example implementation 400 of forming the transistor structure 120 described herein. In some implementations, one or more of the semiconductor processing operations described in connection with FIGS. 4A-4H may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 4A, the operations described in the example implementation 400 may be performed in connection with an ILD layer 112 of the interconnect layer 104 of the semiconductor device 100. The operations described in the example implementation 400 may be performed in connection with forming the semiconductor device 100, as described in connection with FIGS. 3A-3F. For example, the operations described in the example implementation 400 may be performed in connection with forming the interconnect layer 104, as described in connection with FIG. 3E.

As shown in FIG. 4A, the gate electrode 202 may be formed on the ILD layer 112. A deposition tool may deposit the gate electrode 202 using a CVD technique, a PVD technique, an ALD technique, an electroplating technique, and/or a deposition technique other than as described above in connection with FIG. 1. In some implementations, a planarization tool may be used to perform a chemical mechanical planarization (CMP) operation to planarize the gate electrode 202 after the gate electrode 202 is deposited.

As shown in FIG. 4B, the bottom high-k terminal layer 214 may be formed over and/or on the gate electrode 202. A deposition tool may be used to deposit the bottom high-k terminal layer 214 using an ALD technique, a CVD technique, a PVD technique, and/or another suitable deposition technique. In some implementations, a planarization tool is used to perform a CMP operation to planarize the bottom high-k terminal layer 214 after the bottom high-k terminal layer 214 is deposited.

As further shown in FIG. 4B, the gate dielectric layer 204 may be formed above the gate electrode 202. In particular, the gate dielectric layer 204 may be formed on the bottom high-k terminal layer 214. A deposition tool may deposit the gate dielectric layer 204 using a CVD technique, a PVD technique, an ALD technique, an oxidation technique, and/or another suitable deposition technique. In some implementations, a planarization tool may be used to perform a CMP operation to planarize the gate dielectric layer 204 after the gate dielectric layer 204 is deposited.

As further shown in FIG. 4B, the top high-k terminal layer 216 may be formed over and/or on the gate dielectric layer 204. A deposition tool may be used to deposit the top high-k terminal layer 216 using an ALD technique, a CVD technique, a PVD technique, and/or another suitable deposition technique. In some implementations, a planarization tool is used to perform a CMP operation to planarize the top high-k terminal layer 216 after the top high-k terminal layer 216 is deposited.

In some implementations, the bottom high-k terminal layer 214, the gate dielectric layer 204, and the top high-k terminal layer 216 are formed “in-situ,” meaning that the bottom high-k terminal layer 214, the gate dielectric layer 204, and the top high-k terminal layer 216 are all formed in a processing chamber under a vacuum without breaking the vacuum between deposition of the bottom high-k terminal layer 214, the gate dielectric layer 204, and the top high-k terminal layer 216. In some implementations, the bottom high-k terminal layer 214, the gate dielectric layer 204, and the top high-k terminal layer 216 are formed “ex-situ,” meaning that the bottom high-k terminal layer 214, the gate dielectric layer 204, and the top high-k terminal layer 216 are formed in separate deposition operations. In these implementations, the semiconductor device 100 may be moved between different processing chambers between formation of the bottom high-k terminal layer 214, the gate dielectric layer 204, and the top high-k terminal layer 216.

As shown in FIG. 4C, the oxide-semiconductor channel layer 206 is formed over and/or on the top high-k terminal layer 216. A deposition tool may be used to deposit the oxide-semiconductor channel layer 206 using an ALD technique, a CVD technique, a PVD technique, and/or another suitable deposition technique. In some implementations, a planarization tool is used to perform a CMP operation to planarize the oxide-semiconductor channel layer 206 after the oxide-semiconductor channel layer 206 is deposited.

As shown in FIG. 4D, the capping layer 208 is formed over and/or on the oxide-semiconductor channel layer 206. A deposition tool may be used to deposit the capping layer 208 using an ALD technique, a CVD technique, a PVD technique, and/or another suitable deposition technique. In some implementations, the capping layer 208 is formed using an oxidation technique, in which a dielectric layer is deposited and an oxygen treatment or oxygen-based plasma is used to oxidize the dielectric layer to form the capping layer 208. In some implementations, a planarization tool is used to perform a CMP operation to planarize the capping layer 208 after the capping layer 208 is deposited.

As shown in FIG. 4E the oxide-semiconductor channel layer 206 and the capping layer 208 may be etched to define the channel of the transistor structure 120. In some implementations, a pattern in a photoresist layer is used to etch the oxide-semiconductor channel layer 206 and the capping layer 208. In these implementations, a deposition tool may be used to form the photoresist layer on the capping layer 208. An exposure tool may be used to expose the photoresist layer to a radiation source to pattern the photoresist layer. A developer tool may be used to develop and remove portions of the photoresist layer to expose the pattern. An etch tool may be used to etch the oxide-semiconductor channel layer 206 and the capping layer 208 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the oxide-semiconductor channel layer 206 and/or the capping layer 208 based on a pattern.

As shown in FIG. 4F, additional material of the ILD layer 112 may be formed over and/or on the p-type oxide-semiconductor channel layer 06. Moreover, the additional material of the ILD layer 112 may be formed such that the transistor structure 120 is encapsulated by the ILD layer 112. A deposition tool may be used to deposit the additional material of the ILD layer 112 using an ALD technique, a CVD technique, a PVD technique, an oxidation technique, and/or another suitable deposition technique. In some implementations, a planarization tool is used to perform a CMP operation to planarize the ILD layer 112 after the additional material of the ILD layer 112 is deposited.

As shown in FIG. 4G, recesses 402 and 404 may be formed in and/or through the ILD layer 112 such that portions of the top surface of the oxide-semiconductor channel layer 206 are exposed through the recesses 402 and 404. In some implementations, a pattern in a photoresist layer is used to etch the ILD layer 112 to form the recesses 402 and 404. In these implementations, a deposition tool may be used to form the photoresist layer on the ILD layer 112. An exposure tool may be used to expose the photoresist layer to a radiation source to pattern the photoresist layer. A developer tool may be used to develop and remove portions of the photoresist layer to expose the pattern. An etch tool may be used to etch the ILD layer 112 based on the pattern to form the recesses 402 and 404 in the ILD layer 112. The recesses 402 and 404 may also be formed through the capping layer 208. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 112 based on a pattern.

As shown in FIG. 4H, the source/drain electrodes 210 and 212 are respectively formed in the recesses 402 and 404. The source/drain electrodes 210 and 212 may land on the portions of the oxide-semiconductor channel layer 206 that are exposed in the recesses 402 and 404 such that the source/drain electrodes 210 and 212 are electrically coupled and/or physically coupled with the oxide-semiconductor channel layer 206.

A deposition tool may be used to deposit the source/drain electrodes 210 and 212 using a CVD technique, a PVD technique, an ALD technique, an electroplating technique, and/or another suitable deposition technique. In some implementations, a planarization tool may be used to planarize the top surfaces of the source/drain electrodes 210 and 212 after the source/drain electrodes 210 and 212 are deposited. The planarization of the source/drain electrodes 210 and 212 results in the top surfaces of the source/drain electrodes 210 and 212 and the top surface of the ILD layer 112 being substantially co-planar.

As indicated above, FIGS. 4A-4H are provided as an example. Other examples may differ from what is described with regard to FIGS. 4A-4H.

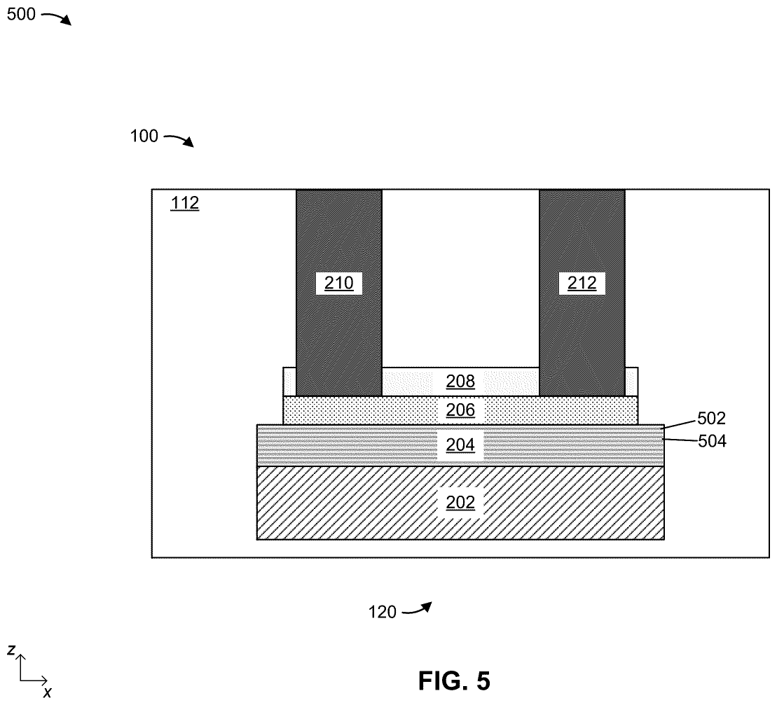

FIG. 5 is a diagram of an example implementation 500 of a transistor structure 120 described herein. As shown in FIG. 5, the example implementation 500 of the transistor structure 120 is similar to the example implementation 200 of the transistor structure 120 illustrated and described in connection with FIGS. 2A and 2B. However, in the example implementation 500 of the transistor structure 120 in FIG. 5, the bottom high-k terminal layer 214 and the top high-k terminal layer 216 are integrated into the gate dielectric layer 204 as doped regions of the gate dielectric layer 204. In other words, doped layers 502 including the high-k dielectric material of the bottom high-k terminal layer 214 and/or of the top high-k terminal layer 216 are situated between layers 504 of the dielectric material of the gate dielectric layer 204. The doped layers 502 of the high-k dielectric material alternate with the layers 504 of the dielectric material of the gate dielectric layer 204 in the z-direction in the semiconductor device 100.

In some implementations, a bottom subset of the doped layers 502 of the high-k dielectric material in the bottom half of the gate dielectric layer 204 includes similar material(s) as the bottom high-k terminal layer 214, and a top subset of the doped layers 502 of the high-k dielectric material in the top half of the gate dielectric layer 204 includes similar material(s) as the top high-k terminal layer 216. Thus, the doped layers 502 of the high-k dielectric material may include different high-k dielectric material(s) as the high-k dielectric material included in the layers 504 of dielectric material of the gate dielectric layer 204. In this way, the bottom subset of the doped layer 502 may promote oxygen-to-metal bonding between the gate dielectric layer 204 and the gate electrode 202, and the top subset of the doped layers 502 also promote oxygen-to-metal bonding between the gate dielectric layer 204 and oxide-semiconductor channel layer 206.

As indicated above, FIG. 5 is provided as an example. Other examples may differ from what is described with regard to FIG. 5.

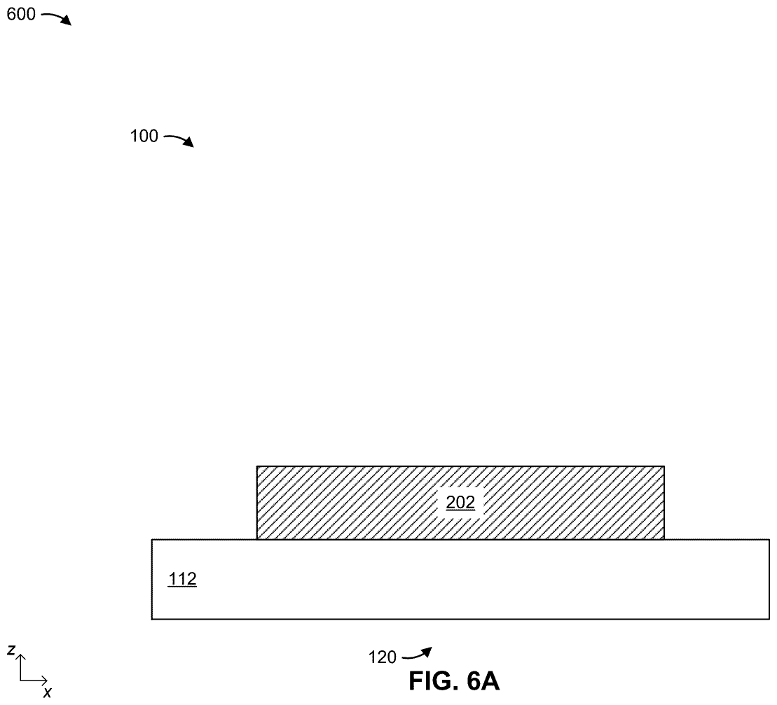

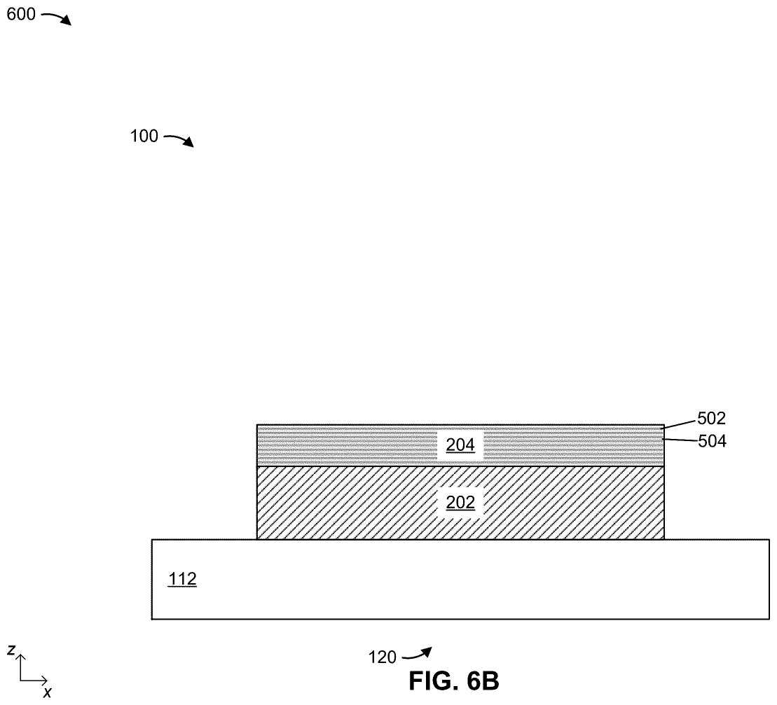

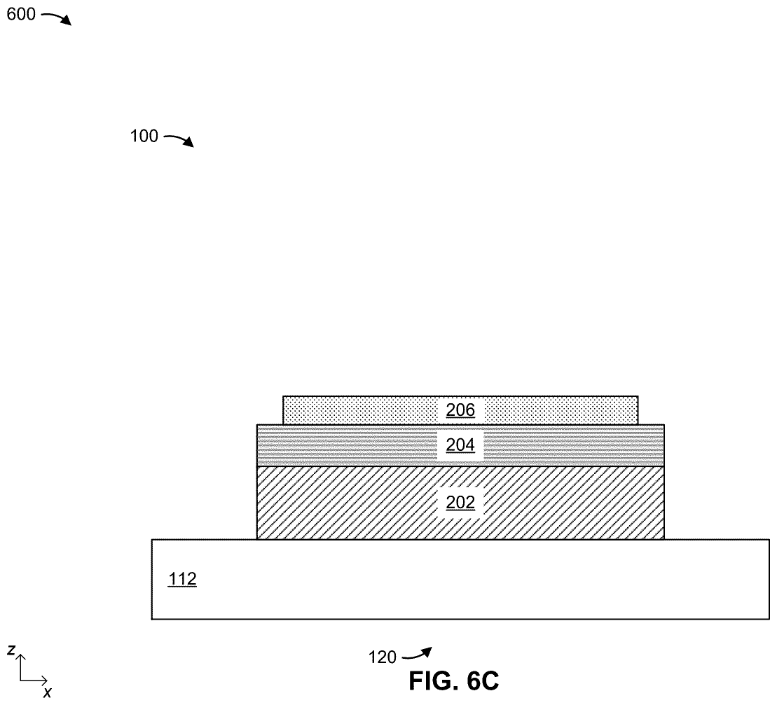

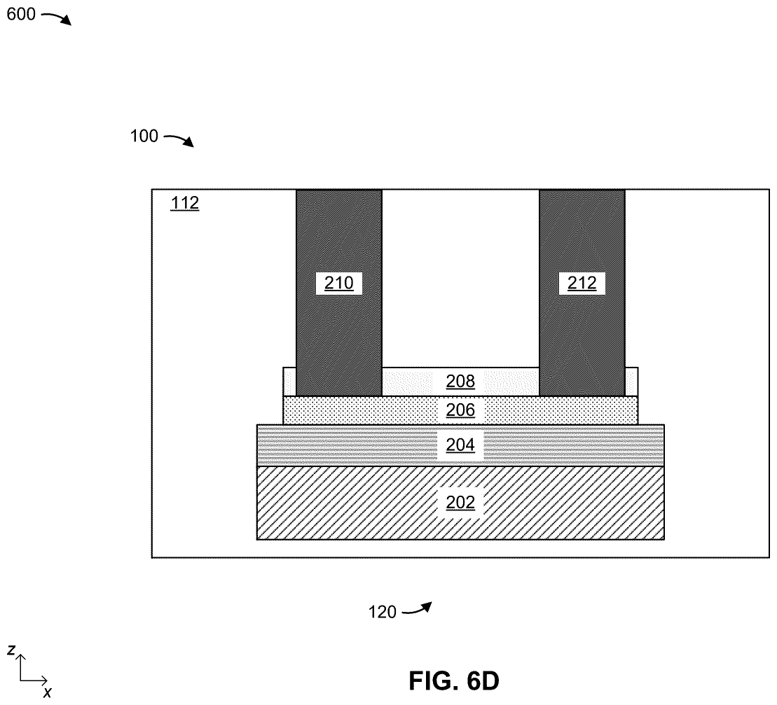

FIGS. 6A-6D are diagrams of an example implementation 600 of forming the transistor structure 120 described herein. In particular, the example implementation 600 includes an example of forming a transistor structure 120 that includes a gate dielectric layer 204 with doped layers 502 described herein. In some implementations, one or more of the semiconductor processing operations described in connection with FIGS. 6A-6D may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 6A, the operations described in the example implementation 400 may be performed in connection with an ILD layer 112 of the interconnect layer 104 of the semiconductor device 100. The operations described in the example implementation 400 may be performed in connection with forming the semiconductor device 100, as described in connection with FIGS. 3A-3F. For example, the operations described in the example implementation 400 may be performed in connection with forming the interconnect layer 104, as described in connection with FIG. 3E.

Turning to FIG. 6A, the operations described in the example implementation 600 may be performed in connection with an ILD layer 112 of the interconnect layer 104 of the semiconductor device 100. The operations described in the example implementation 600 may be performed in connection with forming the semiconductor device 100, as described in connection with FIGS. 3A-3F. For example, the operations described in the example implementation 600 may be performed in connection with forming the interconnect layer 104, as described in connection with FIG. 3E.

As shown in FIG. 6A, the gate electrode 202 may be formed on the ILD layer 112. A deposition tool may deposit the gate electrode 202 using a CVD technique, a PVD technique, an ALD technique, an electroplating technique, and/or a deposition technique other than as described above in connection with FIG. 1. In some implementations, a planarization tool may be used to perform a CMP operation to planarize the gate electrode 202 after the gate electrode 202 is deposited.

As shown in FIG. 6B, the gate dielectric layer 204 is formed on the gate electrode 202. The gate dielectric layer 204 may be doped to form one or more doped regions (e.g., doped layers 502) in between regions (e.g., layers 504) of the high-k dielectric material of the gate dielectric layer 204. In some implementations, an ion implantation tool is used to implant dopants into the high-k dielectric material of the gate dielectric layer 204 to form the doped layers 502. In some implementations, an ALD technique is used to form the doped layers 502 and the layers 504 of the gate dielectric layer 204. For example, ALD may be used to deposit a first atomic layer corresponding to a first layer 504 of the high-k dielectric material the gate dielectric layer 204, a second atomic layer corresponding to a first doped layer 502, a third atomic corresponding to a second layer 504 of the high-k dielectric material the gate dielectric layer 204, a fourth atomic layer corresponding to a second doped layer 502, and so on in a similar manner until a sufficient thickness for the gate dielectric layer 204 is achieved.

As shown in FIG. 6C, the oxide-semiconductor channel layer 206 is formed on the doped gate dielectric layer 204. The oxide-semiconductor channel layer 206 may be formed in a similar manner as described in connection with FIG. 4C.

As shown in FIG. 6D, similar semiconductor processing operations as described in connection with FIGS. 4D-4H may be performed to form the capping layer 208, the source/drain electrodes 210 and 212, and the additional material of the ILD layer 112.

As indicated above, FIGS. 6A-6D are provided as an example. Other examples may differ from what is described with regard to FIGS. 6A-6D.

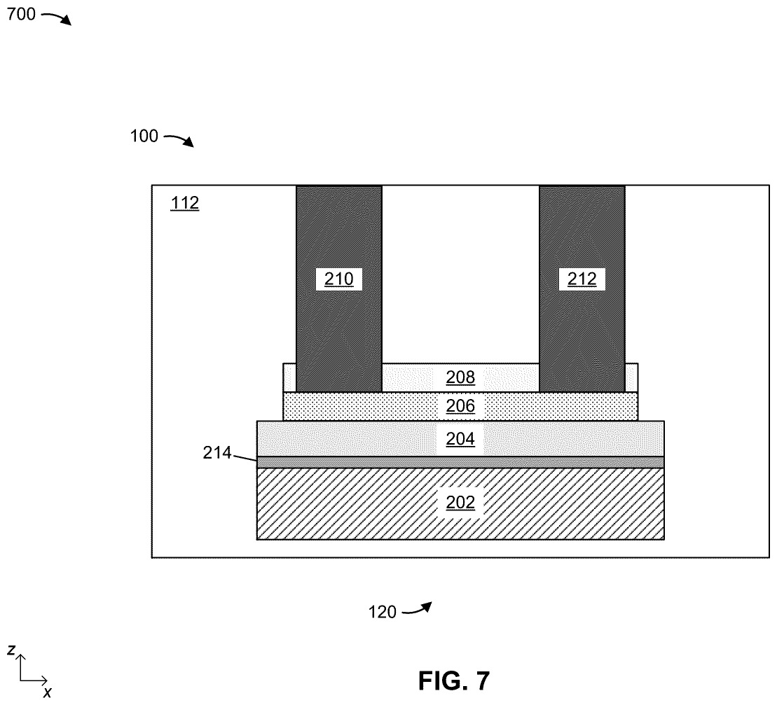

FIG. 7 is a diagram of an example implementation 700 of a transistor structure 120 described herein. As shown in FIG. 7, the example implementation 700 of the transistor structure 120 is similar to the example implementation 200 of the transistor structure 120 illustrated and described in connection with FIGS. 2A and 2B. However, in the example implementation 700 of the transistor structure 120 in FIG. 7, only the bottom high-k terminal layer 214 is included, and the top high-k terminal layer 216 is omitted. Thus, in the example implementation 700 of the transistor structure 120, the oxide-semiconductor channel layer 206 is included on (and formed on) the gate dielectric layer 204 without an intervening high-k terminal layer between the oxide-semiconductor channel layer 206 and the gate dielectric layer 204.

As indicated above, FIG. 7 is provided as an example. Other examples may differ from what is described with regard to FIG. 7.

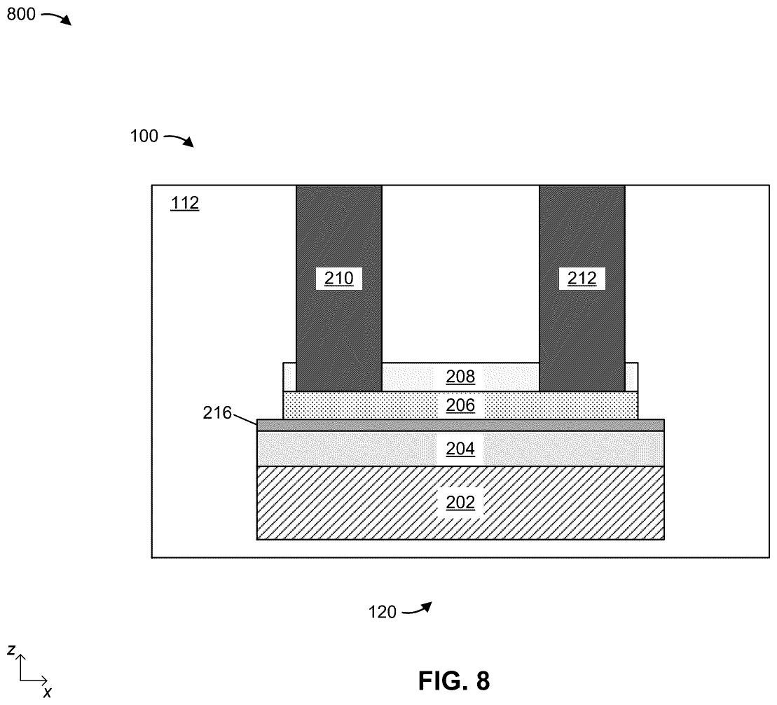

FIG. 8 is a diagram of an example implementation 800 of a transistor structure 120 described herein. As shown in FIG. 8, the example implementation 800 of the transistor structure 120 is similar to the example implementation 200 of the transistor structure 120 illustrated and described in connection with FIGS. 2A and 2B. However, in the example implementation 800 of the transistor structure 120 in FIG. 8, only the top high-k terminal layer 216 is included, and the bottom high-k terminal layer 214 is omitted. Thus, in the example implementation 800 of the transistor structure 120, the gate dielectric layer 204 is included on (and formed on) the gate electrode 202 without an intervening high-k terminal layer between the gate electrode 202 and the gate dielectric layer 204.

As indicated above, FIG. 8 is provided as an example. Other examples may differ from what is described with regard to FIG. 8.

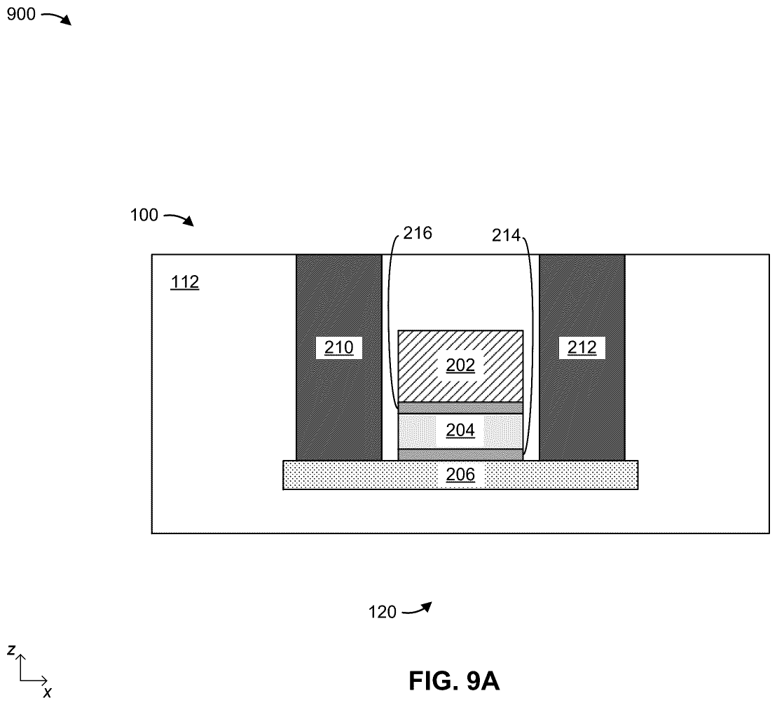

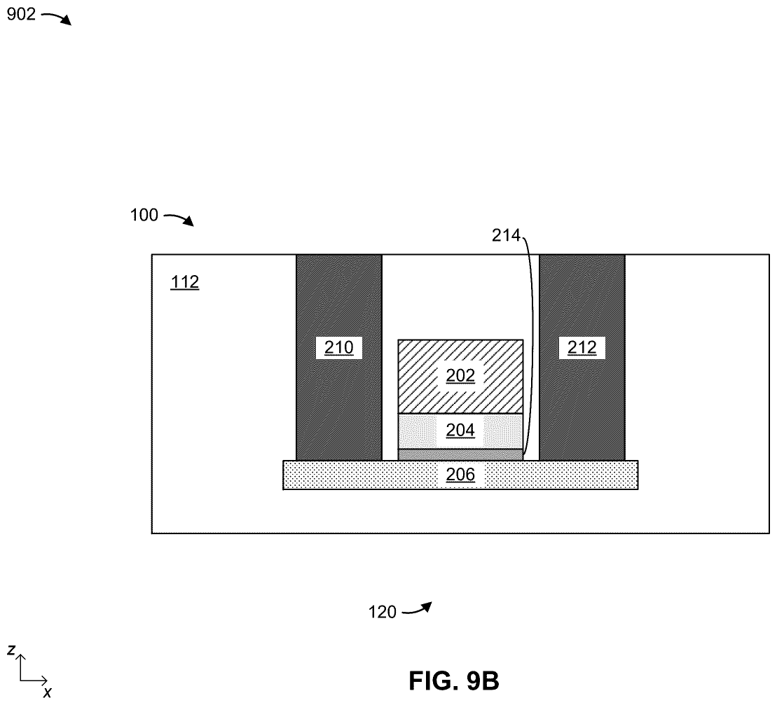

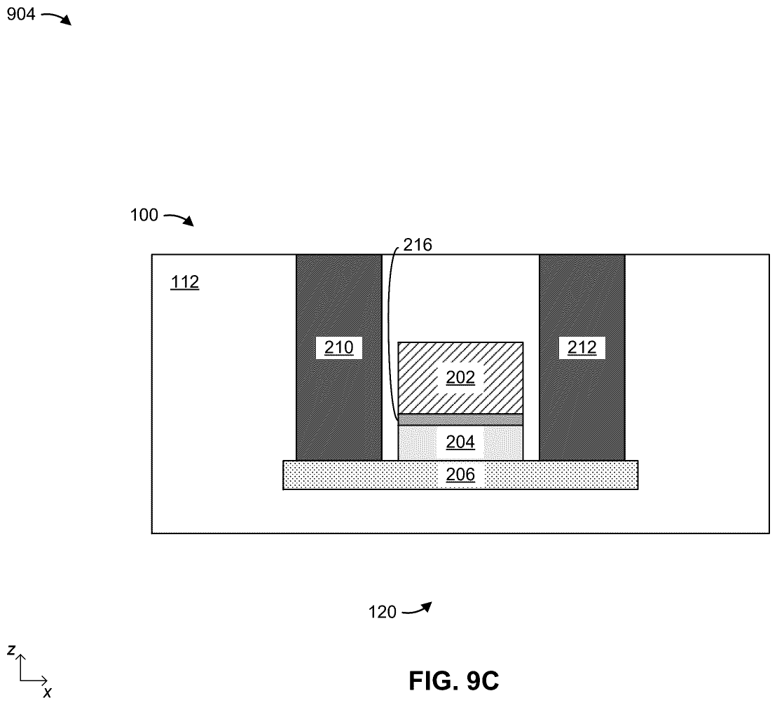

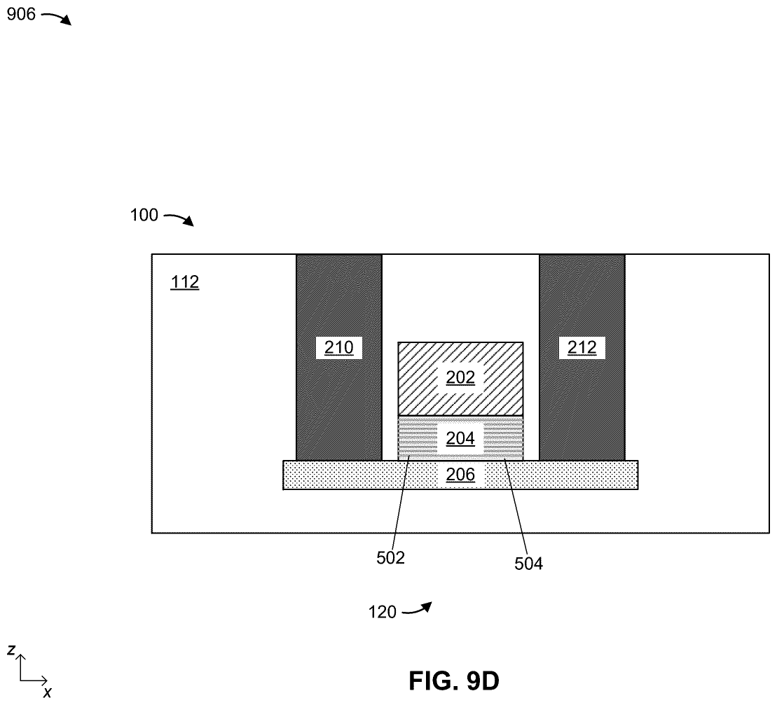

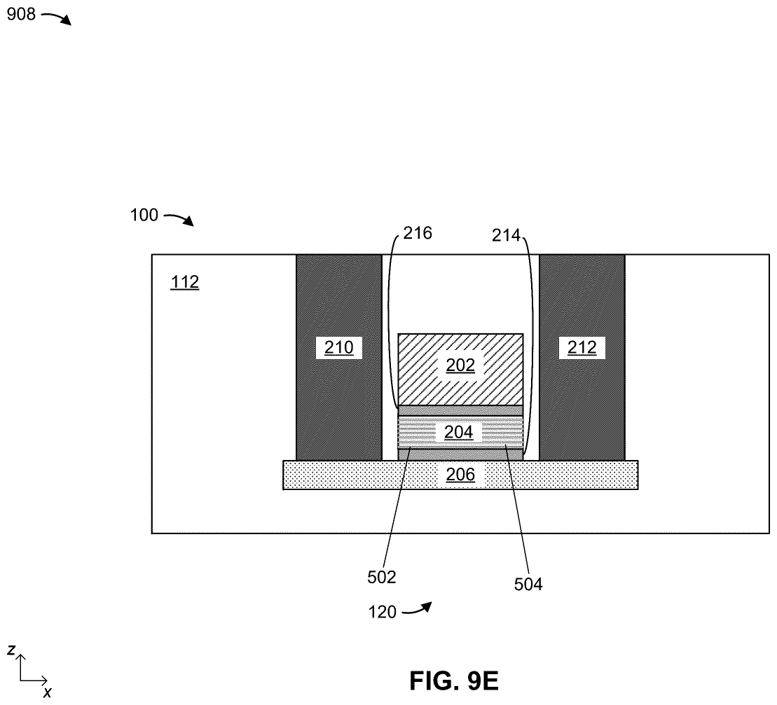

FIGS. 9A-9E are diagrams of example implementations of a transistor structure 120 described herein. FIG. 9A illustrates an example implementation 900 of the transistor structure 120. FIG. 9B illustrates an example implementation 902 of the transistor structure 120. FIG. 9C illustrates an example implementation 904 of the transistor structure 120. FIG. 9D illustrates an example implementation 906 of the transistor structure 120. FIG. 9E illustrates an example implementation 908 of the transistor structure 120.

As shown in FIGS. 9A-9E, the example implementations 900-908 of the transistor structures 120 described herein are similar to the example implementation 200 of the transistor structure 120 illustrated and described in connection with FIG. 2A. For example, the example implementations 900-908 of the transistor structures 120 in FIGS. 9A-9E each include the gate electrode 202, the gate dielectric layer 204, the oxide-semiconductor channel layer 206, and the source/drain electrodes 210 and 212. However, the example implementations 900-906 of the transistor structures 120 in FIGS. 9A-9E each include a top gate electrode as opposed to the bottom gate electrode in the example implementation 200 in FIG. 2A. Thus, in the example implementations 900-906 of the transistor structures 120 in FIGS. 9A-9E, the gate dielectric layer 204 and the gate electrode 202 are included above the oxide-semiconductor channel layer 206, and the gate electrode 202 is included above the gate dielectric layer 204. The gate electrode 202 and the gate dielectric layer 204 are included between the source/drain electrodes 210 and 212. The gate dielectric layer 204 is included between the gate electrode 202 and the oxide-semiconductor channel layer 206.

As shown in the example implementation 900 of the transistor structure 120 in FIG. 9A, the bottom high-k terminal layer 214 is included on the oxide-semiconductor channel layer 206. The gate dielectric layer 204 is included on the bottom high-k terminal layer 214. The top high-k terminal layer 216 is included on the gate dielectric layer 204. The gate electrode 202 is included on the top high-k terminal layer 216. The top high-k terminal layer 216 includes one or more high-k materials that promote oxygen-to-metal bonding between the gate dielectric layer 204 and the gate electrode 202, and the bottom high-k terminal layer 214 includes one or more high-k materials that promote oxygen-to-metal bonding between the gate dielectric layer 204 and oxide-semiconductor channel layer 206.

The bottom high-k terminal layer 214 may be formed prior to formation of the gate electrode 202, and prior to formation of the gate dielectric layer 204. The bottom high-k terminal layer 214 is also formed after formation of the oxide-semiconductor channel layer 206. The bottom high-k terminal layer 214 may be formed in a similar manner as described in connection with FIG. 4B, except that the bottom high-k terminal layer 214 in the example implementation 900 of the transistor structure 120 is formed on the oxide-semiconductor channel layer 206 instead of being formed on the gate electrode 202.

The gate dielectric layer 204 may be formed prior to formation of the gate electrode 202, and prior to formation of the top high-k terminal layer 216. The gate dielectric layer 204 is also formed after formation of the oxide-semiconductor channel layer 206, and after formation of the bottom high-k terminal layer 214. The gate dielectric layer 204 may be formed on the bottom high-k terminal layer 214 in a similar manner as described in connection with FIG. 4B.

The top high-k terminal layer 216 may be formed prior to formation of the gate electrode 202. The top high-k terminal layer 216 is also formed after formation of the gate dielectric layer 204, after formation of the oxide-semiconductor channel layer 206, and after formation of the bottom high-k terminal layer 214. The top high-k terminal layer 216 may be formed on the gate dielectric layer 204 in a similar manner as described in connection with FIG. 4B.

The gate electrode 202 may be formed after formation of the gate dielectric layer 204, after formation of the oxide-semiconductor channel layer 206, and after formation of the bottom high-k terminal layer 214, and after formation of the top high-k terminal layer 216. The gate electrode 202 may be formed on the gate dielectric layer 204 in a similar manner as described in connection with FIG. 4A, except that the gate electrode 202 in the example implementation 900 of the transistor structure 120 is formed on the top high-k terminal layer 216.

As shown in FIG. 9B, the example implementation 902 of the transistor structure 120 is similar to the example implementation 900 of the transistor structure 120 illustrated and described in connection with FIG. 9A. However, in the example implementation 902 of the transistor structure 120, the top high-k terminal layer 216 is omitted and only the bottom high-k terminal layer 214 is included. Thus, in the example implementation 902 of the transistor structure 120, the gate electrode 202 is included on (and formed on) the gate dielectric layer 204 without an intervening high-k terminal layer between the gate electrode 202 and the gate dielectric layer 204.

As shown in FIG. 9C, the example implementation 904 of the transistor structure 120 is similar to the example implementation 900 of the transistor structure 120 illustrated and described in connection with FIG. 9A. However, in the example implementation 904 of the transistor structure 120, the bottom high-k terminal layer 214 is omitted and only the top high-k terminal layer 216 is included. Thus, in the example implementation 904 of the transistor structure 120, the gate dielectric layer 204 is included on (and formed on) the oxide-semiconductor channel layer 206 without an intervening high-k terminal layer between the gate dielectric layer 204 and the oxide-semiconductor channel layer 206.

As shown in FIG. 9D, in the example implementation 904 of the transistor structure 120, the bottom high-k terminal layer 214 and the top high-k terminal layer 216 are omitted. Instead, the gate dielectric layer 204 is doped to include doped layers 502 of the high-k material of the bottom high-k terminal layer 214 and of the top high-k terminal layer 216, in a similar manner as described in connection with FIG. 5.

As shown in FIG. 9E, the example implementation 906 of the transistor structure 120 is similar to the example implementation 900 of the transistor structure 120 illustrated and described in connection with FIG. 9A. However, in the example implementation 906 of the transistor structure 120, the gate dielectric layer 204 is additionally doped to include doped layers 502 of the high-k material of the bottom high-k terminal layer 214 and of the top high-k terminal layer 216, in a similar manner as described in connection with FIG. 5.

As indicated above, FIGS. 9A-9E provided as examples. Other examples may differ from what is described with regard to FIGS. 9A-9E.

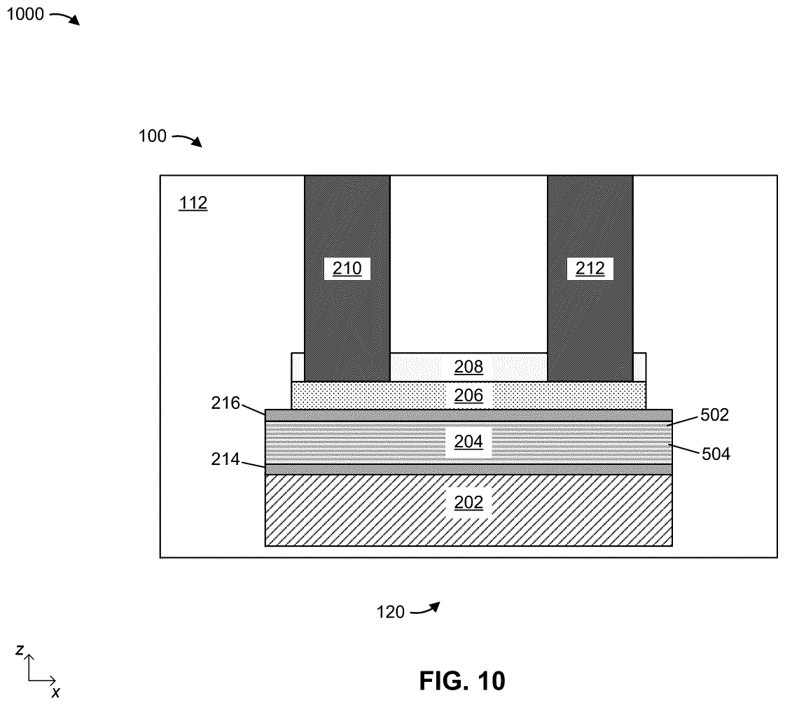

FIG. 10 is a diagram of an example implementation 1000 of a transistor structure 120 described herein. As shown in FIG. 10, the example implementation 1000 of the transistor structure 120 is similar to the example implementation 200 of the transistor structure 120 illustrated and described in connection with FIG. 2A. However, in the example implementation 1000 of the transistor structure 120, the gate dielectric layer 204 is additionally doped to include doped layers 502 of the high-k material of the bottom high-k terminal layer 214 and of the top high-k terminal layer 216, in a similar manner as described in connection with FIG. 5. The bottom high-k terminal layer 214, and one or more of the doped layers 502 in the gate dielectric layer 204, each include one or more high-k materials that promote oxygen-to-metal bonding between the gate dielectric layer 204 and the gate electrode 202. The top high-k terminal layer 216, and one or more of the doped layers 502 in the gate dielectric layer 204, each include one or more high-k materials that promote oxygen-to-metal bonding between the gate dielectric layer 204 and oxide-semiconductor channel layer 206.

As indicated above, FIG. 10 is provided as an example. Other examples may differ from what is described with regard to FIG. 10.

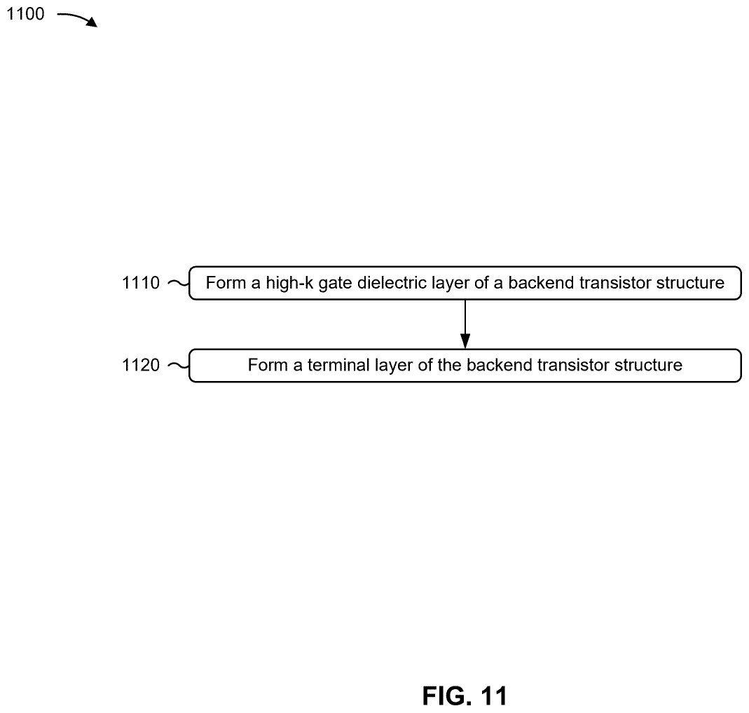

FIG. 11 is a flowchart of an example process 1100 associated with forming a semiconductor device described herein. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include forming a high-k gate dielectric layer of a backend transistor structure (block 1110). For example, one or more semiconductor processing tools may be used to form a high-k gate dielectric layer (e.g., a gate dielectric layer 204) of a backend transistor structure (e.g., a transistor structure 120), as described herein.

As further shown in FIG. 11, process 1100 may include forming a terminal layer (214, 216) of the backend transistor structure (block 1120). For example, one or more semiconductor processing tools may be used to form a terminal layer (e.g., a bottom high-k terminal layer 214, a top high-k terminal layer 216) of the backend transistor structure, as described herein. In some implementations, the terminal layer is vertically adjacent to the high-k gate dielectric layer. In some implementations, the terminal layer includes a first high-k dielectric material that is different from a second high-k dielectric material of the high-k gate dielectric layer.

Process 1100 may include additional implementations, such as any single implementation or any combination of implementations described below and/or in connection with one or more other processes described elsewhere herein.

In a first implementation, forming the high-k gate dielectric layer includes forming the high-k gate dielectric layer on the terminal layer.

In a second implementation, alone or in combination with the first implementation, forming the terminal layer includes forming the terminal layer on the high-k gate dielectric layer.

In a third implementation, alone or in combination with one or more of the first and second implementations, forming the terminal layer includes forming the terminal layer on a gate electrode (e.g., a gate electrode 202) of the backend transistor structure.

In a fourth implementation, alone or in combination with one or more of the first through third implementations, forming the terminal layer includes forming the terminal layer on an oxide-semiconductor channel layer (e.g., an oxide-semiconductor channel layer 206) of the backend transistor structure.

In a fifth implementation, alone or in combination with one or more of the first through fourth implementations, process 1100 includes forming a gate electrode (e.g., a gate electrode 202) on the terminal layer.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

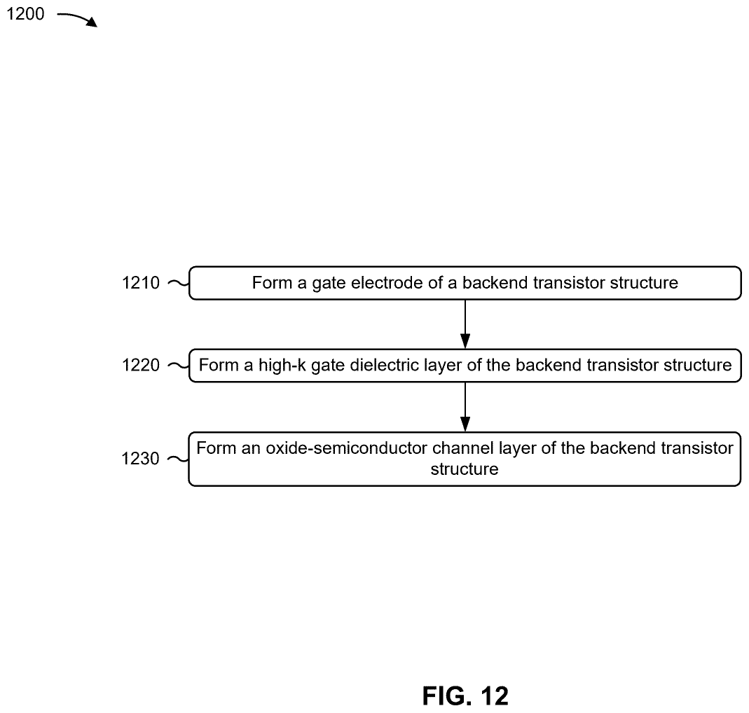

FIG. 12 is a flowchart of an example process 1200 associated with forming a semiconductor device described herein. In some implementations, one or more process blocks of FIG. 12 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 12, process 1200 may include forming a gate electrode of a backend transistor structure (block 1210). For example, one or more semiconductor processing tools may be used to form a gate electrode (e.g., a gate electrode 202) of a backend transistor structure (e.g., a transistor structure 120), as described herein.

As further shown in FIG. 12, process 1200 may include forming a high-k gate dielectric layer of the backend transistor structure (block 1220). For example, one or more semiconductor processing tools may be used to form a high-k gate dielectric layer (e.g., a gate dielectric layer 204) of the backend transistor structure, as described herein. In some implementations, the high-k gate dielectric layer is vertically adjacent to the gate electrode. Forming the gate dielectric layer includes doping the gate dielectric layer to form doped regions (e.g., doped layers 502) of high-k material that is different from the high-k dielectric material of the high-k gate dielectric layer.

As shown in FIG. 12, process 1200 may include forming an oxide-semiconductor channel layer of the backend transistor structure (block 1230). For example, one or more semiconductor processing tools may be used to form an oxide-semiconductor channel layer (e.g., an oxide-semiconductor channel layer 206) of the backend transistor structure, as described herein. In some implementations, the oxide-semiconductor channel layer 206 is vertically adjacent to the high-k gate dielectric layer.

Process 1200 may include additional implementations, such as any single implementation or any combination of implementations described below and/or in connection with one or more other processes described elsewhere herein.

In a first implementation, doping the gate dielectric layer includes doping the gate dielectric layer with one or more of an aluminum oxide (AlₓO_{y}) material, an yttrium oxide (YₓO_{y}) material, a samarium oxide (SmₓO_{y}) material, a gadolinium oxide (GdₓO_{y}) material, a scandium oxide (ScₓO_{y}) material, an ytterbium oxide (YbₓO_{y}) material, or a lutetium oxide (LuₓO_{y}) material.

In a second implementation, alone or in combination with the first implementation, doping the gate dielectric layer includes doping the gate dielectric layer with one or more of a hafnium oxide (HfOₓ) material, a zirconium oxide (ZrOₓ) material, a titanium oxide (TiₓO_{y}) material, a magnesium oxide (MgO) material, a calcium oxide (CaO) material, or a hafnium zirconium oxide (HfₓZr_{y}O_{z}) material.

In a third implementation, doping the gate dielectric layer includes doping the gate dielectric layer to form one or more first doped regions (e.g., one or more first doped layers 502) that include a first high-k material, and doping the gate dielectric layer to form one or more second doped regions (e.g., one or more second doped layers 502) that include a second high-k material that is different form the first high-k material.

Although FIG. 12 shows example blocks of process 1200, in some implementations, process 1200 includes additional blocks, fewer blocks, different blocks, or differently arranged blocks than those depicted in FIG. 1200. Additionally, or alternatively, two or more of the blocks of process 1200 may be performed in parallel.

In this way, a transistor structure may be formed in an interconnect layer of a semiconductor device. The transistor structure is formed such that a bottom high-k terminal layer is included between a gate dielectric layer and an oxide-semiconductor channel layer of the transistor structure, and/or such that a top high-k terminal layer is included between the gate dielectric layer and a gate electrode of the transistor structure. The bottom high-k terminal layer includes one or more materials that promote oxygen-to-metal bonding between the gate dielectric layer and the gate electrode, thereby reducing the likelihood and/or magnitude of charge trapping that might otherwise occur at the interface between the gate dielectric layer and the gate electrode. The top high-k terminal layer also promotes oxygen-to-metal bonding between the gate dielectric layer and oxide-semiconductor channel layer, which passivates loose bonds in the oxide-semiconductor channel layer, thereby reducing the likelihood and/or magnitude of charge trapping that might otherwise occur in the oxide-semiconductor channel layer. In this way, the high-k terminal layers may enable faster switching speeds and/or lesser current leakage to be achieved for the transistor structure.

As described in greater detail above, some implementations described herein provide a transistor structure. The transistor structure includes a gate electrode. The transistor structure includes an oxide-semiconductor channel layer. The transistor structure includes a gate dielectric layer between the gate electrode and the oxide-semiconductor channel layer. The transistor structure includes at least one of, a first high-k terminal layer between the gate electrode and the gate dielectric layer, or a second high-k terminal layer between the gate dielectric layer and the oxide-semiconductor channel layer.

As described in greater detail above, some implementations described herein provide a transistor structure. The transistor structure includes a gate electrode. The transistor structure includes an oxide-semiconductor channel layer. The transistor structure includes a high-k gate dielectric layer between the gate electrode and the oxide-semiconductor channel layer, where the high-k gate dielectric layer includes a first high-k dielectric material, and where the high-k gate dielectric layer includes a plurality of doped regions that include a second high-k dielectric material that is different from the first high-k dielectric material.

As described in greater detail above, some implementations described herein provide a method. The method includes forming a high-k gate dielectric layer of a backend transistor structure. The method includes forming a terminal layer of the backend transistor structure, where the terminal layer is vertically adjacent to the high-k gate dielectric layer, and where the terminal layer includes a first high-k dielectric material that is different from a second high-k dielectric material of the high-k gate dielectric layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor structure, comprising:
a gate electrode;
an oxide-semiconductor channel layer;
a gate dielectric layer between the gate electrode and the oxide-semiconductor channel layer; and
at least one of:
a first high dielectric constant (high-k) terminal layer between the gate electrode and the gate dielectric layer, or
a second high-k terminal layer between the gate dielectric layer and the oxide-semiconductor channel layer.

2. The transistor structure of claim 1, wherein the transistor structure includes the first high-k terminal layer; and
wherein a metal-to-oxygen bonding strength of a high-k material of the first high-k terminal layer is greater than a metal-to-oxygen bonding strength of a dielectric material of the gate dielectric layer.

3. The transistor structure of claim 1, wherein the transistor structure includes the first high-k terminal layer; and
wherein the first high-k terminal layer comprises at least one of:
an aluminum oxide (AlₓO_{y}) material,
an yttrium oxide (YₓO_{y}) material,
a samarium oxide (SmₓO_{y}) material,
a gadolinium oxide (GdₓO_{y}) material,
a scandium oxide (ScₓO_{y}) material,
an ytterbium oxide (YbₓO_{y}) material, or
a lutetium oxide (LuₓO_{y}) material.

4. The transistor structure of claim 1, wherein the transistor structure includes the first high-k terminal layer; and
wherein the first high-k terminal layer comprises a high-k dielectric material having a band gap that is greater than approximately 5 electron-volts.

5. The transistor structure of claim 1, wherein the transistor structure includes the first high-k terminal layer; and
wherein the first high-k terminal layer comprises a high-k dielectric material having a dielectric constant that is greater than approximately 10.

6. The transistor structure of claim 1, wherein the transistor structure includes the second high-k terminal layer; and
wherein a metal-to-oxygen bonding strength of a high-k material of the second high-k terminal layer is approximately equal to a metal-to-oxygen bonding strength of an oxide-semiconductor material of the oxide-semiconductor channel layer.

7. The transistor structure of claim 1, wherein the transistor structure includes the second high-k terminal layer; and
wherein the second high-k terminal layer comprises at least one of:
a hafnium oxide (HfOₓ) material,
a zirconium oxide (ZrOₓ) material,
a titanium oxide (TiₓO_{y}) material,
a magnesium oxide (MgO) material,
a calcium oxide (CaO) material, or
a hafnium zirconium oxide (HfₓZr_{y}O_{z}) material.

8. The transistor structure of claim 1, wherein the transistor structure includes the first high-k terminal layer and the second high-k terminal layer;
wherein the first high-k terminal layer includes a first high-k dielectric material;
wherein the second high-k terminal layer includes a second high-k dielectric material; and
wherein the first high-k dielectric material and the second high-k dielectric material are different high-k dielectric materials.

9. A transistor structure, comprising:
a gate electrode;
an oxide-semiconductor channel layer; and
a high dielectric constant (high-k) gate dielectric layer between the gate electrode and the oxide-semiconductor channel layer,
wherein the high-k gate dielectric layer comprises a first high-k dielectric material, and
wherein the high-k gate dielectric layer comprises a plurality of doped regions that include a second high-k dielectric material that is different from the first high-k dielectric material.

10. The transistor structure of claim 9, wherein the plurality of doped regions comprise a plurality of doped layers including the second high-k dielectric material.

11. The transistor structure of claim 10, wherein the plurality of doped layers alternate with a plurality of layers including the first high-k dielectric material.

12. The transistor structure of claim 9, wherein a band gap of the second high-k dielectric material is greater than a band gap of the first high-k dielectric material.

13. The transistor structure of claim 9, further comprising:
a high dielectric constant (high-k) terminal layer between the gate electrode and the high-k gate dielectric layer.

14. The transistor structure of claim 9, further comprising:
a high-k terminal layer between the high-k gate dielectric layer and the oxide-semiconductor channel layer.

15. A method, comprising:
forming a high dielectric constant (high-k) gate dielectric layer of a backend transistor structure; and
forming a terminal layer of the backend transistor structure,
wherein the terminal layer is vertically adjacent to the high-k gate dielectric layer, and
wherein the terminal layer comprises a first high-k dielectric material that is different from a second high-k dielectric material of the high-k gate dielectric layer.

16. The method of claim 15, wherein forming the high-k gate dielectric layer comprises:
forming the high-k gate dielectric layer on the terminal layer.

17. The method of claim 15, wherein forming the terminal layer comprises:
forming the terminal layer on the high-k gate dielectric layer.

18. The method of claim 15, wherein forming the terminal layer comprises:
forming the terminal layer on a gate electrode of the backend transistor structure.

19. The method of claim 15, wherein forming the terminal layer comprises:
forming the terminal layer on an oxide-semiconductor channel layer of the backend transistor structure.

20. The method of claim 19, further comprising:
forming a gate electrode on the terminal layer.
